(19) United States
(12) Patent Application Publication
(10) Pub. No.: US 2022/0077212 A1
(43) Pub. Date: Mar. 10, 2022

(54) SOLID-STATE IMAGING DEVICE AND ELECTRONIC DEVICE

(71) Applicant: SONY SEMICONDUCTOR SOLUTIONS CORPORATION, KANAGAWA (JP)

(72) Inventors: MASASHI TAKAMI, KANAGAWA (JP); TETSUHIRO IWASHITA, KANAGAWA (JP); TOMOHIKO ASATSUMA, KANAGAWA (JP)

(21) Appl. No.: 17/309,792

(22) PCT Filed: Dec. 27, 2019
(86) PCT No.: PCT/JP2019/051598

§ 371 Date: Jun. 18, 2021

(30) Foreign Application Priority Data
Dec. 28, 2018 (JP) 2018-248447

(51) Int. Cl. H01L 27/146

(52) U.S. Cl. CPC H01L 27/14623; H01L 27/14618; H01L 27/14636

(57) ABSTRACT

To provide a solid-state imaging device that can realize further improvement in image quality. Provided is a solid-state imaging device including: a pixel array unit in which pixels having at least a photoelectric conversion unit configured to perform photoelectric conversion are arranged two-dimensionally; a rib formed in an outer peripheral portion outside the pixel array unit and extending above the pixel array unit; a light-shielding material arranged at least in an outer peripheral portion outside the pixel array unit and further arranged below the rib; and a low-reflection material formed so as to cover at least a part of the light-shielding material. The low-reflection material is formed below the rib, on a side of the rib, or below the rib, and on a side of the rib.

### TECHNICAL FIELD

The present technology relates to a solid-state imaging device and an electronic device.

### BACKGROUND ART

In recent years, electronic cameras have become more popular, and demand for solid-state imaging devices (image sensors), which are core components of electronic cameras, is increasing more and more. Furthermore, in terms of performance of the solid-state imaging devices, development of a technique for realizing high image quality and high functionality has been continued. In considering improvement of the image quality of solid-state imaging devices, it is important to develop a technique for preventing generation of flare (scattered light) that causes deterioration of image quality.

For example, Patent Document 1 proposes a technique for suppressing generation of flare (scattered light) without forming an anti-flare film.

### CITATION LIST

### Patent Document

Patent Document 1: Japanese Patent Application Laid-Open No. 2012-114197

### SUMMARY OF THE INVENTION

### Problems to be Solved by the Invention

However, the technique proposed in Patent Document 1 may not be able to further improve the image quality of the solid-state imaging device.

Therefore, the present technology has been made in view of such a situation, and a main object of the present invention is to provide a solid-state imaging device capable of further improving image quality, and an electronic device equipped with the solid-state imaging device.

### Solutions to Problems

As a result of diligent research to solve the above-mentioned object, the present inventors have succeeded in realizing further improvement in image quality, and have completed the present technology.

That is, the present technology provides a solid-state imaging device including:

pixel array unit in which pixels having at least a photoelectric conversion unit configured to perform photoelectric conversion are arranged two-dimensionally;

a rib formed in an outer peripheral portion outside the pixel array unit and extending above the pixel array unit;

a light-shielding material arranged at least in an outer peripheral portion outside the pixel array unit and further arranged below the rib; and

a low-reflection material formed so as to cover at least a part of the light-shielding material.

In the solid-state imaging device according to the present technology, the low-reflection material may be formed below the rib.

In the solid-state imaging device according to the present technology, the low-reflection material may be formed on a side of the rib.

In the solid-state imaging device according to the present technology, the low-reflection material may be formed below the rib and on a side of the rib.

In the solid-state imaging device according to the present technology, the light-shielding material may be arranged in an outer peripheral portion outside the pixel array unit and in at least a part of the pixel array unit, and may be further arranged below the rib, and

the low-reflection material may be formed below the rib and in at least a part of the pixel array unit so as to cover at least a part of the light-shielding material.

In the solid-state imaging device according to the present technology, the light-shielding material may be arranged in an outer peripheral portion outside the pixel array unit and in at least a part of the pixel array unit, and may be further arranged below the rib, and

the low-reflection material may be formed on a side of the rib and in at least a part of the pixel array unit so as to cover at least a part of the light-shielding material.

In the solid-state imaging device according to the present technology, the light-shielding material may be arranged in an outer peripheral portion outside the pixel array unit and in at least a part of the pixel array unit, and may be further arranged below the rib, and

the low-reflection material may be formed below the rib, on a side of the rib, and in at least a part of the pixel array unit so as to cover at least a part of the light-shielding material.

In the solid-state imaging device according to the present technology, the low-reflection material may be laminated with the light-shielding material via at least one type of oxide film, to be formed below the rib.

In the solid-state imaging device according to the present technology, the low-reflection material may be laminated with the light-shielding material via at least one type of oxide film, to be formed on a side of the rib.

In the solid-state imaging device according to the present technology, the low-reflection material may be laminated with the light-shielding material via at least one type of oxide film, to be formed below the rib and on a side of the rib.

In the solid-state imaging device according to the present technology, the low-reflection material may be a blue filter.

In the solid-state imaging device according to the present technology, the low-reflection material may be a black filter.

Moreover, the present technology provides an electronic device equipped with the solid-state imaging device according to the present technology.

According to the present technology, further improvement in image quality can be realized. Note that the effects described herein are not necessarily limited, and any of the effects described in the present disclosure is possible.

### BRIEF DESCRIPTION OF DRAWINGS

FIG. 1 is a cross-sectional view showing a configuration example of a solid-state imaging device to which the present technology is applied.

FIG. 2 is a cross-sectional view showing a configuration example of a solid-state imaging device of a first embodiment to which the present technology is applied.

FIG. 3 is a cross-sectional view showing a configuration example of a solid-state imaging device of a second embodiment to which the present technology is applied.

FIG. 4 is a cross-sectional view showing a configuration example of a solid-state imaging device of a third embodiment to which the present technology is applied.

FIG. 5 is a cross-sectional view showing a configuration example of a solid-state imaging device of a fourth embodiment to which the present technology is applied.

FIG. 6 is a cross-sectional view showing a configuration example of a solid-state imaging device of a fifth embodiment to which the present technology is applied.

FIG. 7 is a cross-sectional view showing a configuration example of the solid-state imaging device of the second embodiment to which the present technology is applied.

FIG. 8 is a cross-sectional view showing a configuration example of the solid-state imaging device of the fourth embodiment to which the present technology is applied.

FIG. 9 is a cross-sectional view showing a configuration example of the solid-state imaging device of the fifth embodiment to which the present technology is applied.

FIG. 10 is a cross-sectional view showing a configuration example of the solid-state imaging device of the first embodiment to which the present technology is applied.

FIG. 11 is a cross-sectional view showing a configuration example of the solid-state imaging device of the third embodiment to which the present technology is applied.

FIG. 12 is a view showing a configuration example of the solid-state imaging device of the first embodiment to which the present technology is applied.

FIG. 13 is a cross-sectional view showing a configuration example of the solid-state imaging device of the second embodiment to which the present technology is applied.

FIG. 14 is a cross-sectional view showing a configuration example of the solid-state imaging device of the third embodiment to which the present technology is applied.

FIG. 15 is a cross-sectional view showing a configuration example of the solid-state imaging device of the fourth embodiment to which the present technology is applied.

FIG. 16 is a cross-sectional view showing a configuration example of the solid-state imaging device of the fifth embodiment to which the present technology is applied.

FIG. 17 is a cross-sectional view showing a configuration example of a solid-state imaging device.

FIG. 18 is a cross-sectional view showing a configuration example of a solid-state imaging device to which the present technology can be applied.

FIG. 19 is a view showing an outline of a configuration example of a laminated solid-state imaging device to which the present technology can be applied.

FIG. 20 is a cross-sectional view showing a first configuration example of a laminated solid-state imaging device 23020.

FIG. 21 is a cross-sectional view showing a second configuration example of the laminated solid-state imaging device 23020.

FIG. 22 is a cross-sectional view showing a third configuration example of the laminated solid-state imaging device 23020.

FIG. 23 is a cross-sectional view showing another configuration example of a laminated solid-state imaging device to which the present technology can be applied.

FIG. 24 is a conceptual view of a solid-state imaging device to which the present technology can be applied.

FIG. 25 is a circuit diagram showing a specific configuration of a circuit on a first semiconductor chip side and a circuit on a second semiconductor chip side in the solid-state imaging device shown in FIG. 24.

FIG. 26 is a view showing a usage example of the solid-state imaging device of the first to fifth embodiments to which the present technology is applied.

FIG. 27 is a diagram showing a configuration of an imaging device and an electronic device using a solid-state imaging device to which the present technology is applied.

FIG. 28 is a diagram showing an example of a schematic configuration of an endoscopic surgery system.

FIG. 29 is a block diagram showing an example of a functional configuration of a camera head and a CCU.

FIG. 30 is a block diagram showing an example of a schematic configuration of a vehicle control system.

FIG. 31 is an explanatory view showing an example of an installation position of a vehicle external information detection unit and an imaging unit.

### MODE FOR CARRYING OUT THE INVENTION

Hereinafter, a preferred mode for implementing the present technology will be described. The embodiments described below show one example of a representative embodiment of the present technology, and do not cause the scope of the present technology to be narrowly interpreted. Note that, unless otherwise specified, in the drawings, “up” means an upward direction or an upper side in the figure, “down” means a downward direction or a lower side in the figure, “left” means a left direction or a left side in the figure, and “right” means a right direction or a right side in the figure. Furthermore, in the drawings, the same or equivalent elements or members are designated by the same reference numerals, and redundant description will be omitted.

The description will be given in the following order.

1. Outline of present technology

2. First embodiment (Example 1 of solid-state imaging device)

3. Second embodiment (Example 2 of solid-state imaging device)

4. Third embodiment (Example 3 of solid-state imaging device)

5. Fourth Embodiment (Example 4 of solid-state imaging device)

6. Fifth Embodiment (Example 5 of solid-state imaging device)

7. Sixth embodiment (example of electronic device)

8. Usage example of solid-state imaging device to which present technology is applied

9. Application example to endoscopic surgery system

10. Application example to mobile object

### 1. Outline of Present Technology

First, an outline of the present technology will be described.

When an organic material above a light-shielding material (for example, tungsten) is left, the organic material below a rib becomes unstable in terms of film physical characteristics. As a result, for example, there is a case where peeling occurs at an interface between a color filter (an organic material) and a lens material (an organic material). Therefore, measures may be taken to remove the color filter and the lens material below the rib.

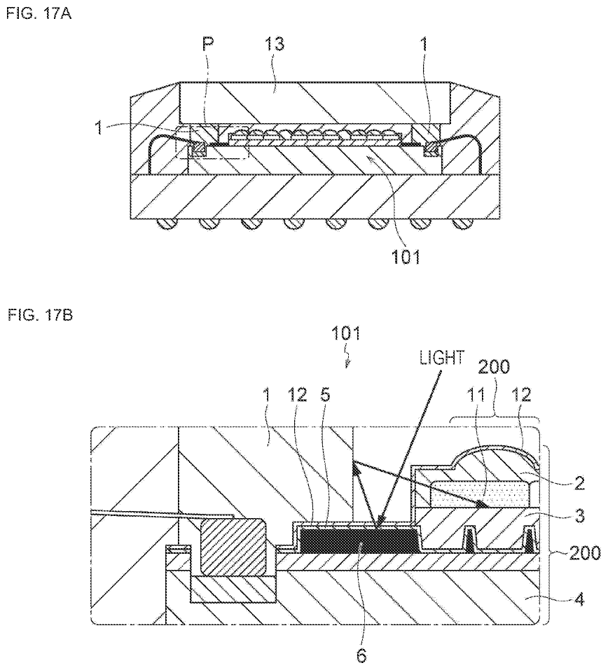

However, as shown in FIG. 17, a first oxide film 5 and a second oxide film 6 are in a state of being formed on a light-shielding material 6 below a rib 1, and the first oxide film 5 and the second oxide film 6 are films that transmit light. Therefore, when light is incident on the rib 1, there is a case where the light reflected by the light-shielding material 6 and the rib 1 enters a light receiving surface of a pixel array unit 200, to cause flare.

The present technology has been made in view of the above. The present technology is a solid-state imaging device including: a pixel array unit in which pixels having at least a photoelectric conversion unit configured to perform photoelectric conversion are arranged two-dimensionally; a rib formed in an outer peripheral portion outside the pixel array unit and extending above the pixel array unit; a light-shielding material arranged at least in an outer peripheral portion outside the pixel array unit and further arranged below the rib; and a low-reflection material formed so as to cover at least a part of the light-shielding material.

According to the present technology, it is possible to reduce reflection of incident light at the rib, prevent generation of flare, and further prevent film peeling below the rib.

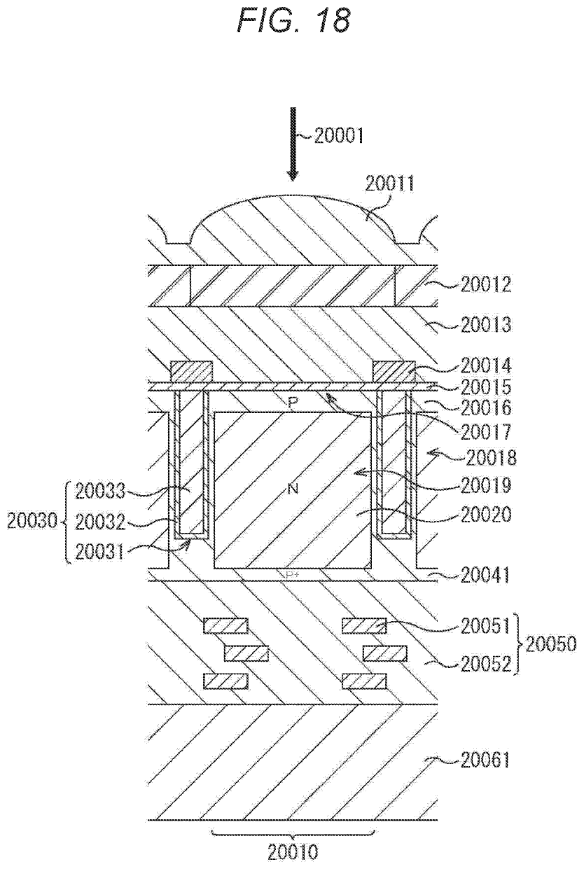

Hereinafter, an example of an overall configuration (a single-layer substrate) of a solid-state imaging device according to the present technology will be described below with reference to FIG. 18.

FIG. 18 is a cross-sectional view showing an overall configuration example of the solid-state imaging device according to the present technology.

In the solid-state imaging device according to the present technology, a photodiode (PD) 20019 receives incident light 20001 incident from a back surface (an upper surface in FIG. 18) side of a semiconductor substrate 20018. Above the PD 20019, a flattening film 20013, a color filter (CF) 20012, and a microlens 20011 are provided, and the incident light 20001 incident through each part is received by a light receiving surface 20017, and photoelectric conversion is performed.

For example, in the PD 20019, an n-type semiconductor region 20020 is formed as a charge accumulation region to accumulate charges (electrons). In the PD 20019, the n-type semiconductor region 20020 is provided inside p-type semiconductor regions 20016 and 20041 of the semiconductor substrate 20018. On a front surface side (a lower surface in FIG. 18) of the semiconductor substrate 20018 in the n-type semiconductor region 20020, the p-type semiconductor region 20041 having a higher impurity concentration than that of a back surface (an upper surface in FIG. 18) side is provided. That is, the PD 20019 has a hole-accumulation diode (HAD) structure, and the p-type semiconductor regions 20016 and 20041 are formed so as to suppress generation of dark current at each interface between an upper surface side and a lower surface side of the n-type semiconductor region 20020.

Inside the semiconductor substrate 20018, a pixel separation unit 20030 that electrically separates between a plurality of pixels 20010 is provided, and the PD 20019 is provided in a region partitioned by this pixel separation unit 20030. In a case where the solid-state imaging device is viewed from an upper surface side in the figure, the pixel separation unit 20030 is formed in a grid pattern so as to intervene between the plurality of pixels 20010, for example, and the PD 20019 is formed in a region partitioned by the pixel separation unit 20030.

In each PD 20019, an anode is grounded. In the solid-state imaging device, signal charges (for example, electrons) accumulated by the PD 20019 are read out via a transfer Tr (MOS FET) or the like (not illustrated), and outputted as an electric signal to a vertical signal line (VSL) (not illustrated).

In the semiconductor substrate 20018, a wiring layer 20050 is provided on a front surface (a lower surface) opposite to a back surface (an upper surface) where each part of a light-shielding film 20014, the CF 20012, the microlens 20011 and the like are provided.

The wiring layer 20050 includes wiring 20051 and an insulation layer 20052, and is formed in the insulation layer 20052 such that the wiring 20051 is electrically connected to each element. The wiring layer 20050 is a so-called multilayer wiring layer, and is formed by alternately layering an interlayer insulating film included in the insulation layer 20052 and the wiring 20051 multiple times. Here, as the wiring 20051, wiring to the Tr to read electric charges from the PD 20019 such as the transfer Tr, and each of wiring such as the VSL are laminated via the insulation layer 20052.

On a surface of the wiring layer 20050 opposite to a side on which the PD 20019 is provided, a support substrate 20061 is provided. For example, a substrate including a silicon semiconductor having a thickness of several hundred μm is provided as the support substrate 20061.

The light-shielding film 20014 is provided on a back surface side (the upper surface in FIG. 18) of the semiconductor substrate 20018.

The light-shielding film 20014 is configured to block a part of the incident light 20001 from above the semiconductor substrate 20018 toward the back surface of the semiconductor substrate 20018.

The light-shielding film 20014 is provided above the pixel separation unit 20030 provided inside the semiconductor substrate 20018. Here, on the back surface (the upper surface) of the semiconductor substrate 20018, the light-shielding film 20014 is provided so as to protrude in a projecting shape via an insulating film 20015 such as a silicon oxide film. On the other hand, above the PD 20019 provided inside the semiconductor substrate 20018, the light-shielding film 20014 is not provided, and there is an opening such that the incident light 20001 is incident on the PD 20019.

That is, in a case where the solid-state imaging device is viewed from an upper surface side in the figure, a planar shape of the light-shielding film 20014 is a grid pattern, and an opening that allows the incident light 20001 to pass to the light receiving surface 20017 is formed.

The light-shielding film 20014 is formed by a light-shielding material that blocks light. For example, the light-shielding film 20014 is formed by sequentially laminating a titanium (Ti) film and a tungsten (W) film. In addition to this, the light-shielding film 20014 can be formed by, for example, sequentially laminating a titanium nitride (TiN) film and a tungsten (W) film.

The light-shielding film 20014 is covered with the flattening film 20013. The flattening film 20013 is formed by using an insulating material that transmits light.

The pixel separation unit 20030 has a groove portion 20031, a fixed charge film 20032, and an insulating film 20033.

The fixed charge film 20032 is formed on the back surface (the upper surface) side of the semiconductor substrate 20018 so as to cover the groove portion 20031 that partitions between the plurality of pixels 20010.

Specifically, the fixed charge film 20032 is provided so as to cover an inner surface of the groove portion 20031 formed on the back surface (the upper surface) side of the semiconductor substrate 20018 with a constant thickness. Then, the insulating film 20033 is provided (filled in) so as to fill inside of the groove portion 20031 covered with the fixed charge film 20032.

Here, the fixed charge film 20032 is formed by using a high dielectric having a negative fixed charge so as to form a positive charge (hole) accumulation region at an interface with the semiconductor substrate 20018 so as to suppress generation of dark current. By forming the fixed charge film 20032 so as to have a negative fixed charge, the negative fixed charge causes an electric field to be applied to the interface with the semiconductor substrate 20018, to form the positive charge (hole) accumulation region.

The fixed charge film 20032 can be formed by, for example, a hafnium oxide film (HfO₂ film). Furthermore, in addition to this, the fixed charge film 20032 can be formed so as to include at least one of, for example, oxides of hafnium, zirconium, aluminum, tantalum, titanium, magnesium, yttrium, lanthanoid elements, and the like.

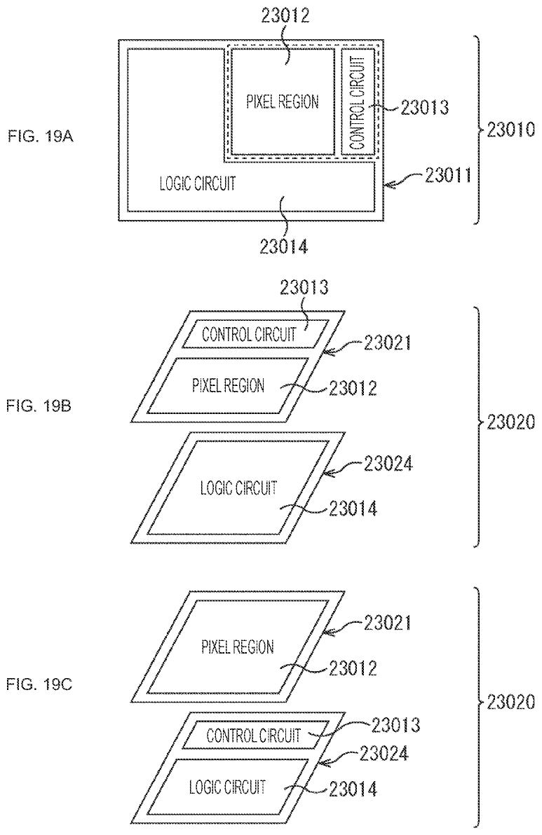

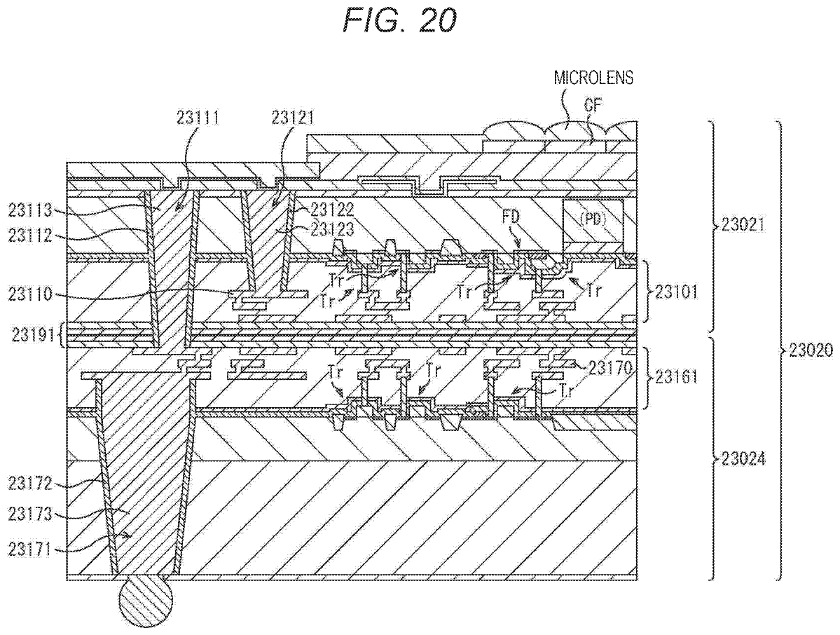

Next, an overall configuration example (a laminated substrate) of the solid-state imaging device according to the present technology will be described with reference to FIGS. 19 to 20.

FIG. 19 is a view showing an outline of a configuration example of a laminated solid-state imaging device to which the technology according to the present disclosure can be applied.

A of FIG. 19 shows a schematic configuration example of a non-laminated solid-state imaging device. A solid-state imaging device 23010 has one die (a semiconductor substrate) 23011 as shown in A of FIG. 19. This die 23011 is equipped with a pixel region 23012 in which pixels are arranged in an array, a control circuit 23013 configured to drive pixels and perform other various controls, and a logic circuit 23014 configured to perform signal processing.

B and C in FIG. 19 show a schematic configuration example of a laminated solid-state imaging device. In a solid-state imaging device 23020, as shown in B and C of FIG. 19, two dies, a sensor die 23021 and a logic die 23024, are laminated, and electrically connected to be configured as one semiconductor chip.

In B of FIG. 19, the sensor die 23021 is equipped with a pixel region 23012 and a control circuit 23013, and a logic die 23024 is equipped with the logic circuit 23014 including a signal processing circuit configured to perform signal processing.

In C of FIG. 19, the sensor die 23021 is equipped with a pixel region 23012, and the logic die 23024 is equipped with a control circuit 23013 and a logic circuit 23014.

FIG. 20 is a cross-sectional view showing a first configuration example of the laminated solid-state imaging device 23020.

The sensor die 23021 is formed with a photodiode (PD), floating diffusion (FD), and a Tr (MOS FET), which form a pixel to be the pixel region 23012, and a Tr or the like that is to be the control circuits 23013. Moreover, the sensor die 23021 is formed with a wiring layer 23101 having a plurality of layers, in this example, three layers of wiring 23110. Note that (a Tr that is to be) the control circuit 23013 can be configured on the logic die 23024 instead of the sensor die 23021.

On the logic die 23024, a Tr included in the logic circuit 23014 is formed. Moreover, the logic die 23024 is formed with a wiring layer 23161 having a plurality of layers, in this example, three layers of wiring 23170. Furthermore, the logic die 23024 is formed with a connection hole 23171 in which an insulating film 23172 is formed on an inner wall surface, and a connecting conductor 23173 connected to the wiring 23170 or the like is embedded in the connection hole 23171.

The sensor die 23021 and the logic die 23024 are bonded such that the wiring layers 23101 and 23161 face each other. As a result, the laminated solid-state imaging device 23020 in which the sensor die 23021 and the logic die 23024 are laminated is configured. On a surface on which the sensor die 23021 and the logic die 23024 are bonded, a film 23191 such as a protective film is formed.

The sensor die 23021 is formed with a connection hole 23111 that penetrates the sensor die 23021 and reaches the wiring 23170 on a top layer of the logic die 23024 from a back surface side (a side where light is incident on the PD) (an upper side) of the sensor die 23021. Moreover, the sensor die 23021 is formed with a connection hole 23121 that reaches the wiring 23110 of the first layer from the back surface side of the sensor die 23021 in proximity to the connection hole 23111. On an inner wall surface of the connection hole 23111, an insulating film 23112 is formed. On an inner wall surface of the connection hole 23121, an insulating film 23122 is formed. Then, in the connection holes 23111 and 23121, connecting conductors 23113 and 23123 are embedded, respectively. The connecting conductor 23113 and the connecting conductor 23123 are electrically connected on the back surface side of the sensor die 23021. As a result, the sensor die 23021 and the logic die 23024 are electrically connected via the wiring layer 23101, the connection hole 23121, the connection hole 23111, and the wiring layer 23161.

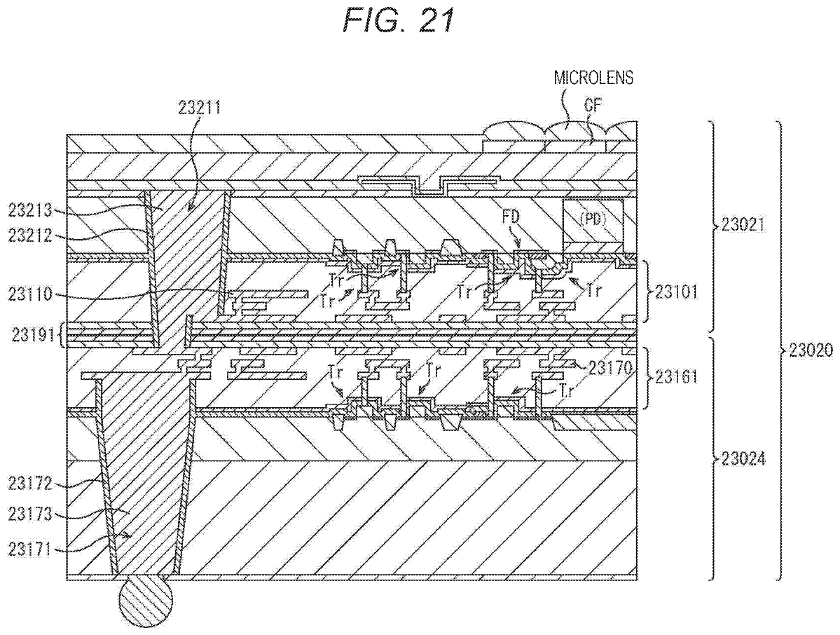

FIG. 21 is a cross-sectional view showing a second configuration example of the laminated solid-state imaging device 23020.

In the second configuration example of the solid-state imaging device 23020, one connection hole 23211 formed in the sensor die 23021 electrically connects ((the wiring 23110 of) the wiring layer 23101 of) the sensor die 23021 and ((the wiring 23170 of) the wiring layer 23161 of) the logic die 23024.

That is, in FIG. 21, the connection hole 23211 is formed so as to penetrate the sensor die 23021 from the back surface side of the sensor die 23021 and reach the wiring 23170 on a top layer of the logic die 23024, and to reach the wiring 23110 on a top layer of the sensor die 23021. On an inner wall surface of the connection hole 23211, an insulating film 23212 is formed, and a connecting conductor 23213 is embedded in the connection hole 23211. In FIG. 20 described above, the sensor die 23021 and the logic die 23024 are electrically connected by the two connection holes 23111 and 23121, but the sensor die 23021 and the logic die 23024 are electrically connected by one connection hole 23211 in FIG. 21.

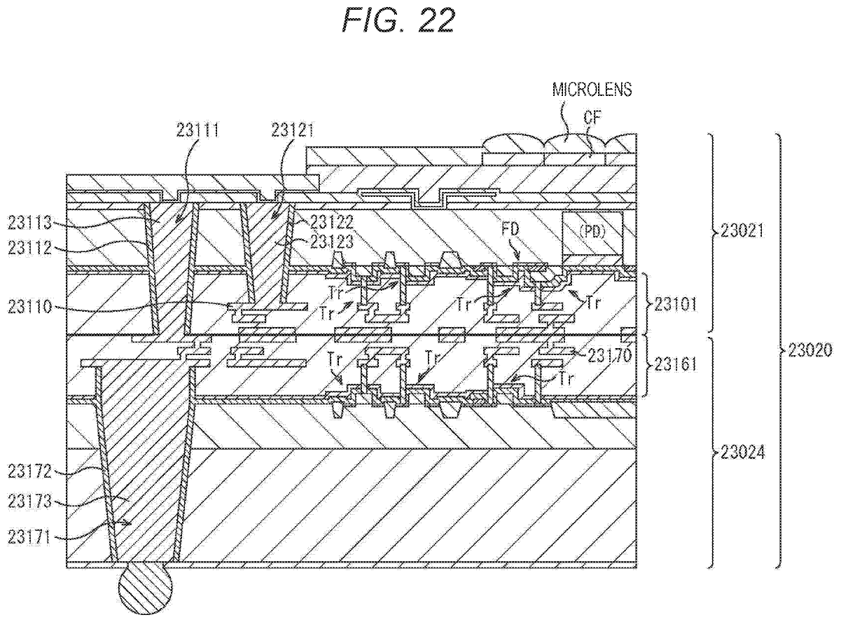

FIG. 22 is a cross-sectional view showing a third configuration example of the laminated solid-state imaging device 23020.

The solid-state imaging device 23020 shown in FIG. 22 is different from a case of FIG. 20 in which the film 23191 such as a protective film is formed on the surface on which the sensor die 23021 and the logic die 23024 are bonded, in that the film 23191 such as a protective film is not formed on the surface on which the sensor die 23021 and the logic die 23024 are bonded.

The solid-state imaging device 23020 in FIG. 22 is configured by layering the sensor die 23021 and the logic die 23024 such that the wiring 23110 and the wiring 23170 are in direct contact, and directly joining the wiring 23110 and the wiring 23170 by heating while applying a required weight.

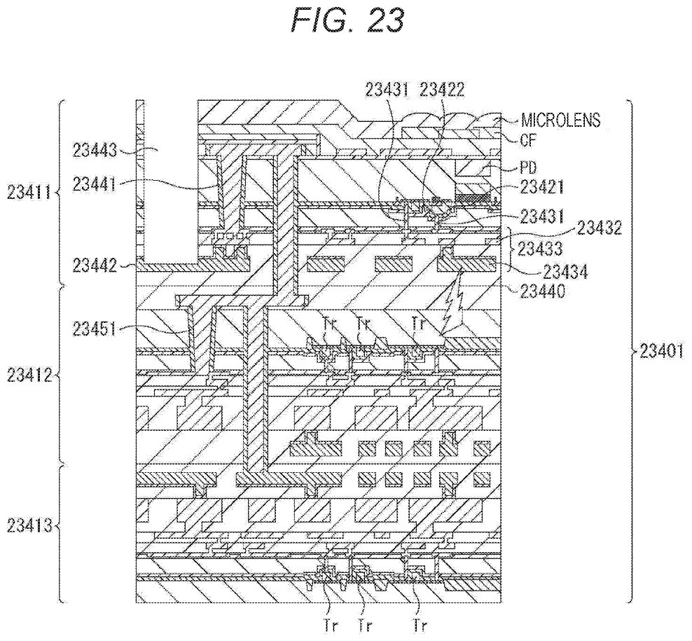

FIG. 23 is a cross-sectional view showing another configuration example of a laminated solid-state imaging device to which the technology according to the present disclosure can be applied.

In FIG. 23, a solid-state imaging device 23401 has a three-layer laminated structure in which three dies of a sensor die 23411, a logic die 23412, and a memory die 23413 are laminated.

The memory die 23413 has, for example, a memory circuit that stores data temporarily required for signal processing performed by the logic die 23412.

In FIG. 23, the logic die 23412 and the memory die 23413 are laminated in this order under the sensor die 23411, but the logic die 23412 and the memory die 23413 can be laminated under the sensor die 23411 in a reverse order, that is, an order of the memory die 23413 and the logic die 23412.

Note that, in FIG. 23, the sensor die 23411 is formed with a PD serving as a pixel photoelectric conversion unit, and with a source/drain region of a pixel Tr.

Around the PD, a gate electrode is formed via a gate insulating film, and a pixel Tr 23421 and a pixel Tr 23422 are formed by a source/drain region paired with the gate electrode.

The pixel Tr 23421 adjacent to the PD is a transfer Tr, and one of the paired source/drain regions included in the pixel Tr 23421 is an FD.

Furthermore, an interlayer insulating film is formed in the sensor die 23411, and a connection hole is formed in the interlayer insulating film. In the connection hole, the pixel Tr 23421 and a connecting conductor 23431 connected to the pixel Tr 23422 are formed.

Moreover, the sensor die 23411 is formed with a wiring layer 23433 having a plurality of layers of wiring 23432 connected to each connecting conductor 23431.

Furthermore, in a bottom layer of the wiring layer 23433 of the sensor die 23411, an aluminum pad 23434 that is an electrode for external connection is formed. That is, in the sensor die 23411, the aluminum pad 23434 is formed at a position closer to a bonding surface 23440 with the logic die 23412 than the wiring 23432. The aluminum pad 23434 is used as one end of wiring related to input and output of signals to and from outside.

Moreover, the sensor die 23411 is formed with a contact 23441 used for electrical connection with the logic die 23412. The contact 23441 is connected to a contact 23451 of the logic die 23412 and also to an aluminum pad 23442 of the sensor die 23411.

Then, to the sensor die 23411, a pad hole 23443 is formed to reach the aluminum pad 23442 from a back surface side (an upper side) of the sensor die 23411.

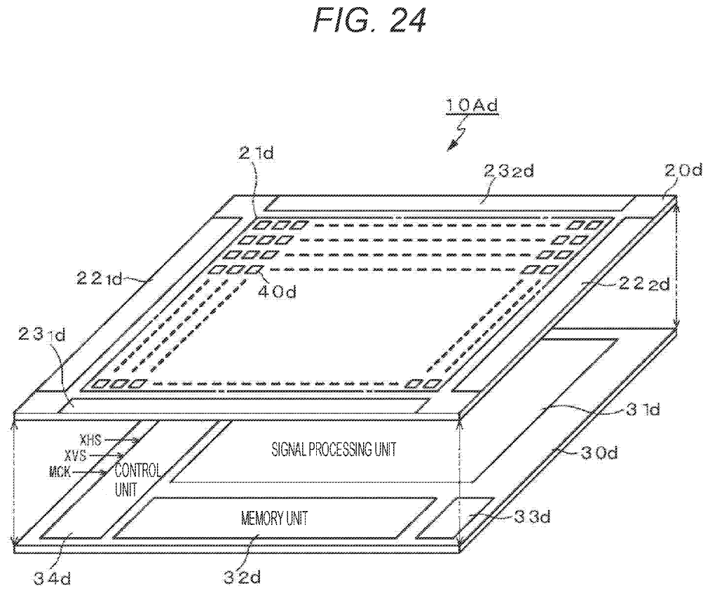

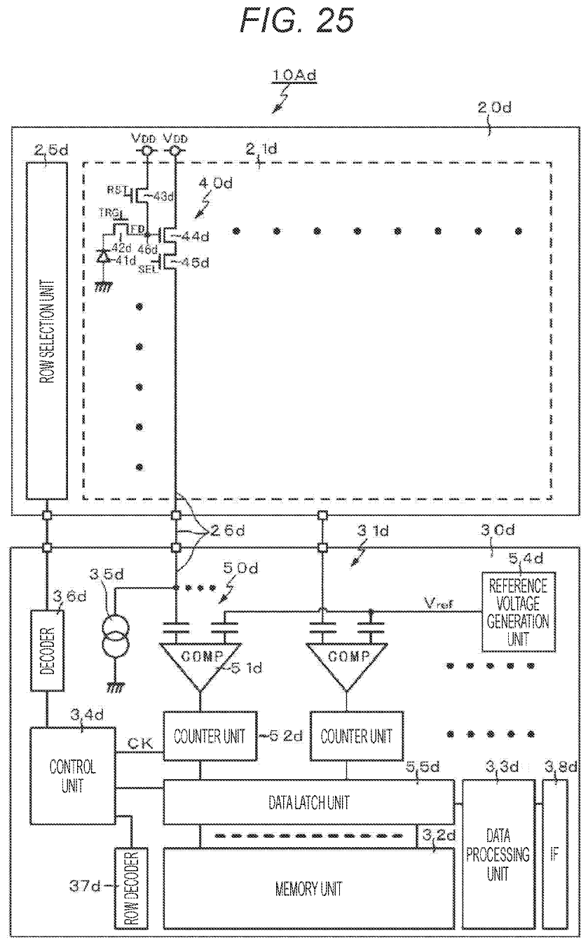

Moreover, a configuration example (a circuit configuration on a laminated substrate) of a laminated solid-state imaging device to which the present technology can be applied will be described with reference to FIGS. 24 and 25.

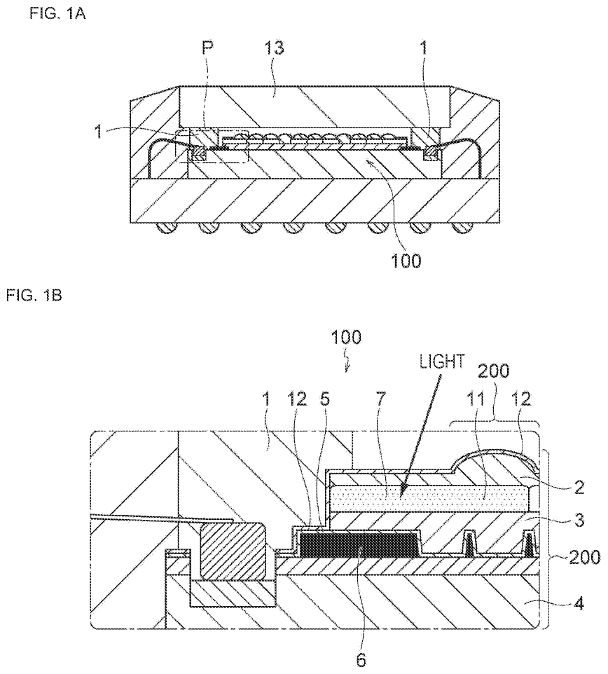

An electronic device (a laminated solid-state imaging device) 10Ad shown in FIG. 24 includes: a first semiconductor chip 20d having a sensor unit 21d in which a plurality of sensors 40d is arranged; and a second semiconductor chip 30d having a signal processing unit 31d configured to process a signal acquired by the sensor 40d. The first semiconductor chip 20d and the second semiconductor chip 30d are laminated, and at least a part of the signal processing unit 31d is configured with a depletion type field effect transistor. Note that the plurality of sensors 40d is arranged in a two-dimensional matrix (matrix form). This similarly applies to the following description. Note that, in FIG. 1, for the sake of explanation, the first semiconductor chip 20d and the second semiconductor chip 30d are illustrated in a separated state.

Furthermore, the electronic device 10Ad includes: the first semiconductor chip 20d having the sensor unit 21d in which the plurality of sensors 40d is arranged; and the second semiconductor chip 30d having the signal processing unit 31d configured to process a signal acquired by the sensor 40d. The first semiconductor chip 20d and the second semiconductor chip 30d are laminated, the signal processing unit 31d is configured with a high withstand voltage transistor system circuit and a low withstand voltage transistor system circuit, and at least a part of the low withstand voltage transistor system circuit is configured with a depletion type field effect transistor.

The depletion type field effect transistor has a complete depletion type SOI structure, or has a partial depletion type SOI structure, or has a fin structure (also called a double gate structure or a tri-gate structure), or has a deep depletion channel structure. A configuration and a structure of these depletion type field effect transistors will be described later.

Specifically, as shown in FIG. 25, the sensor unit 21d and a row selection unit 25d are arranged on the first semiconductor chip 20d. Whereas, the signal processing unit 31d is arranged on the second semiconductor chip 30d. The signal processing unit 31d includes: an analog-to-digital converter (hereinafter abbreviated as an “AD converter”) 50d equipped with a comparator 51d and a counter unit 52d; a ramp voltage generator (hereinafter sometimes referred to as a “reference voltage generation unit”) 54d; a data latch unit 55d; a parallel-serial conversion unit 56; a memory unit 32d; a data processing unit 33d; a control unit 34d (including a clock supply unit connected to the AD converter 50d); a current source 35d; a decoder 36d; a row decoder 37d; and an interface (IF) unit 38b.

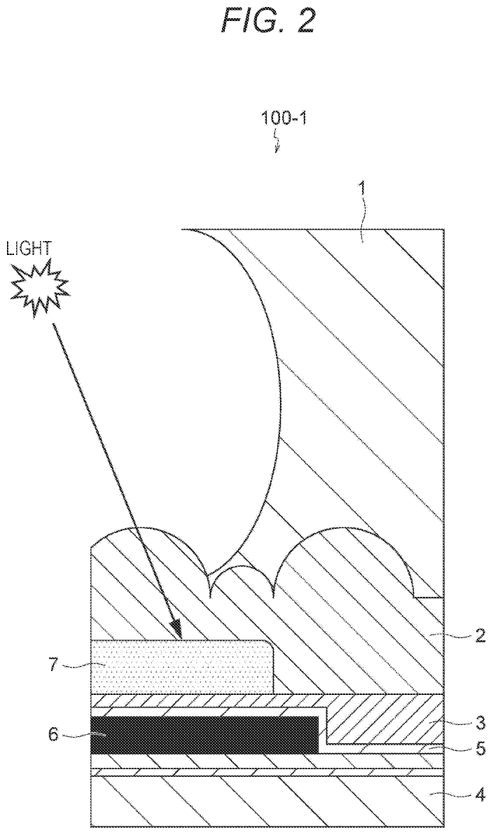

Then, for the electronic device, the high withstand voltage transistor system circuit in the second semiconductor chip 30d (a specific configuration circuit will be described later) is planarly overlapped with the sensor unit 21d in the first semiconductor chip 20d. Further, in the second semiconductor chip 30d, a light-shielding region is formed above the high withstand voltage transistor system circuit facing the sensor unit 21d of the first semiconductor chip 20d. In the second semiconductor chip 30d, the light-shielding region arranged below the sensor unit 21d can be obtained by appropriately arranging wiring (not illustrated) formed in the second semiconductor chip 30d. Furthermore, in the second semiconductor chip 30d, the AD converter 50d is arranged below the sensor unit 21d. Here, the signal processing unit 31d or the low withstand voltage transistor system circuit (a specific configuration circuit will be described later) includes a part of the AD converter 50d, and at least a part of the AD converter 50d is configured with a depletion type field effect transistor. Specifically, the AD converter 50d is configured with a single slope type AD converter whose circuit diagram is shown in FIG. 2. Alternatively, the electronic device may have a configuration in which, as another layout, the high withstand voltage transistor system circuit in the second semiconductor chip 30d is not planarly overlapped with the sensor unit 21d in the first semiconductor chip 20d. That is, in the second semiconductor chip 30d, a part of the analog-to-digital converter 50d and the like are arranged in an outer peripheral portion of the second semiconductor chip 30d. Then, this arrangement eliminates necessity of forming a light-shielding region, which makes it possible to simplify a process, a structure, and a configuration, improve a degree of freedom in design, and reduce restrictions in layout design.

One AD converter 50d is provided for a plurality of sensors 40d (sensors 40d belonging to one sensor column). The AD converter 50d configured by a single-slope analog-to-digital converter has: the ramp voltage generator (the reference voltage generation unit) 54d; the comparator 51d inputted with an analog signal acquired by the sensor 40d and a ramp voltage from the ramp voltage generator (the reference voltage generation unit) 54d; and the counter unit 52d that is supplied with a clock CK from the clock supply unit (not illustrated) provided in the control unit 34d and operates on the basis of an output signal of the comparator 51d. Note that the clock supply unit connected to the AD converter 50d is included in the signal processing unit 31d or the low withstand voltage transistor system circuit (more specifically, included in the control unit 34d), and configured with a well-known PLL circuit. Then, at least a part of the counter unit 52d and the clock supply unit are configured with a depletion type field effect transistor.

That is, the sensor unit 21d (the sensor 40d) and the row selection unit 25d provided on the first semiconductor chip 20d, and a column selection unit 27, which will be described later, correspond to the high withstand voltage transistor system circuit. Furthermore, the comparators 51d included in the AD converter 50d in the signal processing unit 31d provided on the second semiconductor chip 30d, the ramp voltage generator (the reference voltage generation unit) 54d, the current source 35d, the decoder 36d, and the interface (IF) unit 38b correspond to the high withstand voltage transistor system circuit. Whereas, the counter unit 52d included in the AD converter 50d in the signal processing unit 31d provided on the second semiconductor chip 30d, the data latch unit 55d, the parallel-serial conversion unit 56, the memory unit 32d, the data processing unit 33d (including an image signal processing unit), the control unit 34d (including the clock supply unit and a timing control circuit connected to the AD converter 50d), and the row decoder 37d, as well as a multiplexer (MUX) 57 and a data compression unit 58, which will be described later, correspond to the low withstand voltage transistor system circuit. Then, all of the counter unit 52d and the clock supply unit included in the control unit 34d are configured with a depletion type field effect transistor.

In order to obtain a laminated structure of the first semiconductor chip 20d and the second semiconductor chip 30d, first, on the basis of a well-known method, the above-mentioned various predetermined circuits are formed on a first silicon semiconductor substrate included in the first semiconductor chip 20d and a second silicon semiconductor substrate included in the second semiconductor chip 30d. Then, the first silicon semiconductor substrate and the second silicon semiconductor substrate are bonded together on the basis of a well-known method. Next, by forming a through hole from wiring formed on the first silicon semiconductor substrate side to wiring formed on the second silicon semiconductor substrate, and filling the through hole with a conductive material, TC (S) V is formed. Thereafter, by forming a color filter and a microlens on the sensor 40d as desired, and then dicing the bonded structure of the first silicon semiconductor substrate and the second silicon semiconductor substrate, it is possible to obtain the electronic device 10Ad in which the first semiconductor chip 20d and the second semiconductor chip 30d are laminated.

The sensor 40d is specifically configured with an image sensor, more specifically with a CMOS image sensor having a well-known configuration and structure, and the electronic device 10Ad is configured with a solid-state imaging device. The solid-state imaging device is an XY address type solid-state imaging device that can read a signal (an analog signal) from the sensor 40d for each sensor group in units of one sensor, or units of multiple sensors, or units of one or more rows (lines). Then, in the sensor unit 21d, a control line (a row control line) is wired for each sensor row for a matrix-shaped sensor array, and a signal line (a column signal line/vertical signal line) 26 is wired for each sensor column. A configuration may be adopted in which the current source 35d is connected to each of the signal lines 26d. Then, a signal (an analog signal) is read from the sensor 40d of the sensor unit 21d via the signal line 26d. A configuration may be adopted in which this reading is performed, for example, under a rolling shutter that exposes in units of one sensor or one line (one row) of a sensor group. This reading under the rolling shutter may be referred to as “rolling reading”.

At a peripheral edge of the first semiconductor chip 20d, there are provided pad portions 221 and 222 for electrical connection between with the outside, and via portions 231 and 232 having a TC (S) V structure for electrical connection between with the second semiconductor chip 30d. Note that, in the drawings, the via portion may be referred to as “VIA”. Here, the pad portion 221 and the pad portion 222 are provided on both left and right sides with the sensor unit 21d interposed in between in this configuration, but may be provided on one of the left and right sides. Furthermore, in this configuration, the via portion 231 and the via portion 232 are provided on both upper and lower sides with the sensor unit 21d interposed in between, but may be provided on one of the upper and lower sides. Furthermore, it is also possible to adopt a configuration in which a bonding pad portion is provided on the second semiconductor chip 30d on a lower side, an opening is provided on the first semiconductor chip 20d, and wire bonding is performed to the bonding pad portion provided on the second semiconductor chip 30d via the opening provided on the first semiconductor chip 20d, or a configuration in which substrate mounting is performed using a TC (S) V structure from the second semiconductor chip 30d. Alternatively, the electrical connection between a circuit in the first semiconductor chip 20d and a circuit in the second semiconductor chip 30d can be made via a bump on the basis of a chip-on-chip method. The analog signal obtained from each sensor 40d of the sensor unit 21d is transmitted from the first semiconductor chip 20d to the second semiconductor chip 30d via the via portions 231 and 232. Note that, in this specification, concepts of “left side”, “right side”, “upper side”, “lower side”, “up and down”, “up and down direction”, “left and right”, and “left and right direction” are concepts that express a relative positional relationship when the drawings are viewed. This similarly applies to the following.

A circuit configuration on the first semiconductor chip 20d side will be described with reference to FIG. 2. On the first semiconductor chip 20d side, in addition to the sensor unit 21d in which the sensors 40d are arranged in a matrix, there is provided the row selection unit 25d configured to select each sensor 40d of the sensor unit 21d in units of row on the basis of an address signal given from the second semiconductor chip 30d side. Note that the row selection unit 25d is provided on the first semiconductor chip 20d side here, but can also be provided on the second semiconductor chip 30d side.

As shown in FIG. 25, the sensor 40d has, for example, a photodiode 41d as a photoelectric conversion element. In addition to the photodiode 41d, the sensor 40d has, for example, four transistors, a transfer transistor (a transfer gate) 42, a reset transistor 43d, an amplification transistor 44d, and a selection transistor 45d. For example, N-channel transistors are used as the four transistors 42d, 43d, 44d, and 45d. However, a combination of the transfer transistor 42d, the reset transistor 43d, the amplification transistor 44d, and the selection transistor 45d exemplified here is only an example, and the combination is not limited to these. That is, if necessary, a combination using a P-channel type transistor can be adopted. Furthermore, these transistors 42d, 43d, 44d, and 45d are configured with high withstand voltage MOS transistors. That is, as described above, the sensor unit 21d is a high withstand voltage transistor system circuit as a whole.

A transfer signal TRG, a reset signal RST, and a selection signal SEL, which are drive signals for driving the sensor 40d, are appropriately given to the sensor 40d from the row selection unit 25d. That is, the transfer signal TRG is applied to a gate electrode of the transfer transistor 42d, the reset signal RST is applied to a gate electrode of the reset transistor 43d, and the selection signal SEL is applied to a gate electrode of the selection transistor 45d.

In the photodiode 41d, an anode electrode is connected to a low potential side power supply (for example, a ground), photoelectrically converts received light (incident light) into a photoelectric charge (here, a photoelectron) having a charge amount corresponding to a light amount, and accumulates the photoelectric charge. A cathode electrode of the photodiode 41d is electrically connected to a gate electrode of the amplification transistor 44d via the transfer transistor 42d. A node 46 electrically connected to the gate electrode of the amplification transistor 44d is called an FD part (a floating diffusion/a floating diffusion region part).

The transfer transistor 42d is connected between the cathode electrode of the photodiode 41d and the FD part 46d. To the gate electrode of the transfer transistor 42d, the transfer signal TRG in which a high level (for example, a V_{DD} level) is active (hereinafter referred to as “High active”) is given from the row selection unit 25d. In response to this transfer signal TRG, the transfer transistor 42d is brought into a conductive state, and a photoelectric charge photoelectrically converted by the photodiode 41d is transferred to the FD part 46d. A drain region of the reset transistor 43d is connected to a sensor power supply V_{DD}, and a source region is connected to the FD part 46d. To the gate electrode of the reset transistor 43d, a High active reset signal RST is given from the row selection unit 25d. In response to this reset signal RST, the reset transistor 43d is brought into a conductive state, and the FD part 46d is reset by discarding the charge of the FD part 46d to the sensor power supply V_{DD}. The gate electrode of the amplification transistor 44d is connected to the FD part 46d, and a drain region is connected to the sensor power supply V_{DD}. Then, the amplification transistor 44d outputs the potential of the FD part 46d after being reset by the reset transistor 43d, as a reset signal (reset level: V_{Reset}). The amplification transistor 44d further outputs potential of the FD part 46d after the signal charge is transferred by the transfer transistor 42d as an optical storage signal (a signal level) V_{sig}. For example, a drain region of the selection transistor 45d is connected to a source region of the amplification transistor 44d, and a source region is connected to the signal line 26d. To the gate electrode of the selection transistor 45d, a High active selection signal SEL is given from the row selection unit 25d. In response to this selection signal SEL, the selection transistor 45d is brought into a conductive state, the sensor 40d is brought into a selection state, a signal (an analog signal) of the signal level V_{sig} outputted from the amplification transistor 44d is sent to the signal line 26d.

In this way, sequentially to the signal line 26d from the sensor 40d, the potential of the FD part 46d after the reset is read out with the reset level V_{Reset}, and then the potential of the FD part 46d after the transfer of the signal charge is read out with the signal level V_{sig}. The signal level V_{sig} also includes a component of the reset level V_{Reset}. Note that, in this circuit configuration, the selection transistor 45d is connected between the source region of the amplification transistor 44d and the signal line 26d. However, a circuit configuration may be adopted in which the selection transistor 45d is connected between the sensor power supply V_{DD} and the drain region of the amplification transistor 44d.

Furthermore, the sensor 40d is not limited to such a configuration including the four transistors. For example, it is possible to adopt a configuration including three transistors in which the amplification transistor 44d has the function of the selection transistor 45d, a configuration in which transistors in and after the FD part 46d can be shared between multiple photoelectric conversion elements (sensors), or the like, and any circuit configuration may be adopted.

As shown in FIGS. 24 and 25 and as described above, in the electronic device 10Ad, the second semiconductor chip 30d is provided with the memory unit 32d, the data processing unit 33d, the control unit 34d, the current source 35d, the decoder 36d, the row decoder 37d, the interface (IF) unit 38b, and the like, and further provided with a sensor driving unit (not illustrated) configured to drive each sensor 40d of the sensor unit 21d. The signal processing unit 31d can have a configuration in which predetermined signal processing including digitization (AD conversion) is performed on an analog signal read from each sensor 40d of the sensor unit 21d for every sensor row, in parallel (column parallel) in units of sensor column. Then, the signal processing unit 31d has the AD converter 50d that digitizes an analog signal read from each sensor 40d of the sensor unit 21d to the signal line 26d, and transfers AD-converted image data (digital data) to the memory unit 32d. The memory unit 32d stores image data subjected to predetermined signal processing in the signal processing unit 31d. The memory unit 32d may be configured with a non-volatile memory or may be configured with a volatile memory. The data processing unit 33d reads out image data stored in the memory unit 32d in a predetermined order, performs various processes, and outputs to the outside of the chip. The control unit 34d controls each operation of the sensor driving unit and the signal processing unit 31d such as the memory unit 32d and the data processing unit 33d on the basis of, for example, reference signal such as a horizontal sync signal XHS, a vertical sync signal XVS, and a master clock MCK given from outside the chip. At this time, the control unit 34d performs the control while synchronizing a circuit on the first semiconductor chip 20d side (the row selection unit 25d and the sensor unit 21d) with the signal processing unit 31d (the memory unit 32d, the data processing unit 33d, and the like) on the second semiconductor chip 30d side.

The current source 35d is connected with each of the signal lines 26d to which the analog signal is read out for every sensor column from each sensor 40d of the sensor unit 21d. The current source 35d has a so-called load MOS circuit configuration including a MOS transistor whose gate potential is biased to a constant potential, for example, to supply a constant current to the signal line 26d. The current source 35d including this load MOS circuit operates the amplification transistor 44d as a source follower, by supplying a constant current to the amplification transistor 44d of the sensor 40d included in a selected row. In selecting each sensor 40d of the sensor unit 21d in units of row under the control of the control unit 34d, the decoder 36d gives an address signal for specifying an address of the selected row to the row selection unit 25d. The row decoder 37d specifies a row address when writing image data to the memory unit 32d and reading image data from the memory unit 32d under the control of the control unit 34d.

As described above, the signal processing unit 31d has at least the AD converter 50d that digitizes (AD converts) an analog signal read from each sensor 40d of the sensor unit 21d through the signal line 26d, and performs signal processing (column parallel AD) in parallel on an analog signal in units of sensor column. The signal processing unit 31d further has the ramp voltage generator (the reference voltage generation unit) 54d that generates a reference voltage Vref used for AD conversion by the AD converter 50d. The reference voltage generation unit 54d generates the reference voltage Vref of a so-called RAMP waveform (a gradient waveform) in which a voltage value changes stepwise over time. The reference voltage generation unit 54d can be configured by using, for example, a DA converter (a digital-to-analog converter), but is not limited to this.

The AD converter 50d is provided, for example, for each sensor column of the sensor unit 21d, that is, for each signal line 26d. That is, the AD converter 50d is a so-called column-parallel AD converter that is arranged as many as the number of sensor columns of the sensor unit 21d. Then, the AD converter 50d generates, for example, a pulse signal having magnitude (a pulse width) corresponding to magnitude of a level of the analog signal in a time axis direction, and measures a length of a pulse width period of this pulse signal, to perform AD conversion processing. More specifically, as shown in FIG. 2, the AD converter 50d has at least the comparator (COMP) 51d and the counter unit 52d. While an analog signal (the signal level V_{sig} and the reset level V_{Reset} described above) read out from each sensor 40d of the sensor unit 21d via the signal line 26d is used as a comparison input, and the reference voltage Vref of a ramp waveform supplied from the reference voltage generation unit 54d is used as a reference input, the comparator 51d compares both inputs. The ramp waveform is a waveform in which a voltage changes in an inclined manner (stepwise) with passage of time. Then, an output of the comparator 51d is in a first state (for example, a high level) when the reference voltage Vref becomes larger than the analog signal, for example. Whereas, when the reference voltage Vref is equal to or less than the analog signal, the output is in a second state (for example, a low level). The output signal of the comparator 51d becomes a pulse signal having a pulse width corresponding to the magnitude of the level of the analog signal.

As the counter unit 52d, for example, an up/down counter is used. The clock CK is given to the counter unit 52d at the same timing as a supply start timing of the reference voltage Vref to the comparator 51d. The counter unit 52d, which is an up/down counter, measures a period of a pulse width of the output pulse of the comparator 51d, that is, a comparison period from a start of the comparison operation to an end of the comparison operation, by performing a down count or an up count in synchronization with the clock CK. During this measurement operation, for the reset level V_{Reset} and the signal level V_{sig} sequentially read out from the sensor 40d, the counter unit 52d performs the down count for the reset level V_{Reset} and the up count for the signal level V_{sig}. Then, by this down count/up count operation, a difference between the signal level V_{sig} and the reset level V_{Reset} can be obtained. As a result, in the AD converter 50d, correlated double sampling (CDS) processing is performed in addition to the AD conversion processing. Here, the “CDS processing” is processing for removing fixed pattern noise peculiar to the sensor, such as reset noise of the sensor 40d and threshold variation of the amplification transistor 44d, by taking a difference between the signal level V_{sig} and the reset level V_{Reset}. Then, a count result (a count value) of the counter unit 52d becomes a digital value (image data) obtained by digitizing the analog signal.

In this way, in the electronic device 10Ad, which is a solid-state imaging device in which the first semiconductor chip 20d and the second semiconductor chip 30d are laminated, the first semiconductor chip 20d may have any size (area) that is large enough to form the sensor unit 21d. Therefore, the size (the area) of the first semiconductor chip 20d, and accordingly a size of the entire chip can be reduced. Moreover, a process suitable for manufacturing the sensor 40d can be applied to the first semiconductor chip 20d, and a process suitable for manufacturing various circuits can be applied to the second semiconductor chip 30d individually, which can optimize the process in the manufacture of the electronic device 10Ad. Furthermore, by adopting a configuration of providing a circuit part for analog/digital processing on the same substrate (the second semiconductor chip 30d) and synchronizing and controlling the circuit on the first semiconductor chip 20d side and the circuit on the second semiconductor chip 30d side while transmitting an analog signal from the first semiconductor chip 20d side to the second semiconductor chip 30d side, high-speed processing can be realized.

Hereinafter, a solid-state imaging device of embodiments (a first embodiment to a fourth embodiment) according to the present technology will be described concretely and in detail.

### 2. First Embodiment (Example 1 of Solid-State Imaging Device)

A solid-state imaging device of a first embodiment (Example 1 of a solid-state imaging device) according to the present technology is a solid-state imaging device including: a pixel array unit in which pixels having at least a photoelectric conversion unit configured to perform photoelectric conversion are arranged two-dimensionally; a rib formed in an outer peripheral portion outside the pixel array unit and extending above the pixel array unit; a light-shielding material arranged at least in an outer peripheral portion outside the pixel array unit and further arranged below the rib; and a low-reflection material formed so as to cover at least a part of the light-shielding material. In the solid-state imaging device of the first embodiment according to the present technology, the low-reflection material may be any material that can suppress reflection of light. For example, examples include a material that absorbs light, an antireflection material, and the like. Specifically, examples include organic films such as color filters such as a blue filter that transmits blue light, a green filter that transmits green light, and a red filter that transmits red light, and a black filter. In a case where a color filter is used for the low-reflection material, formation at the same time in a process of forming an on-chip color filter of the pixel array unit is possible, which enables formation of the present embodiment without increasing the number of process steps. Especially in a case of a blue filter, a transmitted wavelength is a short wave length, which makes it possible to further suppress that light transmitted through the blue filter is reflected by the light-shielding material. Furthermore, a black filter is preferable because the black filter can absorb light in a wide wavelength band, transmits less light, and can suppress reflection by the light-shielding material. The low-reflection material may be formed below a rib, formed on a side of the rib, or formed below and on a side of the rib.

Hereinafter, with reference to FIGS. 1, 2, 10, and 12, the solid-state imaging device of the first embodiment according to the present technology will be described.

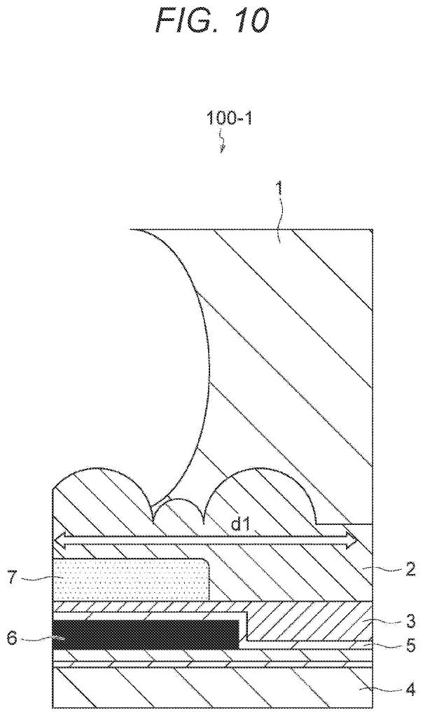

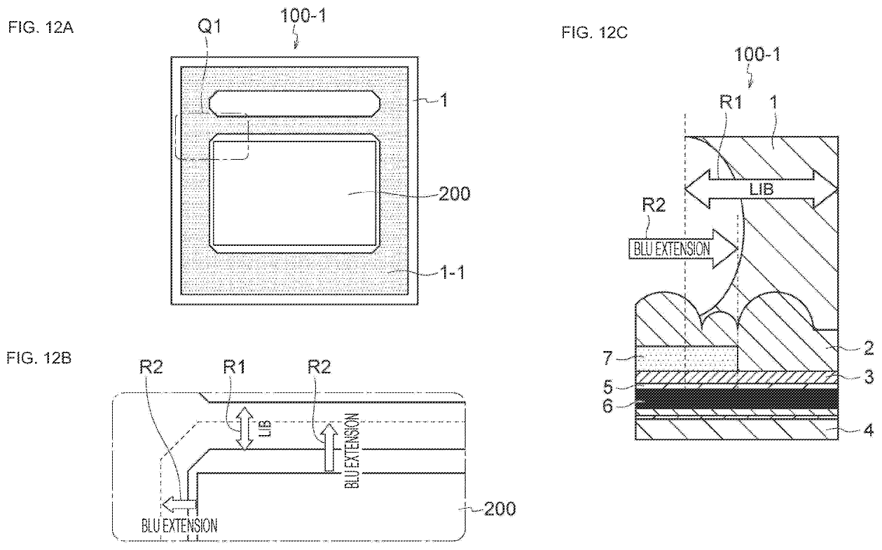

FIG. 1 is a cross-sectional view showing a configuration example of a solid-state imaging device 100 of the first embodiment according to the present technology. FIG. 1(a) is a cross-sectional view showing a state in which the solid-state imaging device 100 is joined to a glass substrate 13 via a rib 1. FIG. 1(b) is an enlarged cross-sectional view showing an enlarged portion P shown in FIG. 1(a). FIG. 2 is a cross-sectional view showing a configuration example of a solid-state imaging device 100-1 of the first embodiment according to the present technology. FIG. 10 is a view for explaining that a width of a low-reflection material 7 can be changed freely in order to further enhance an effect of preventing reflection flare. FIG. 12 is a view showing a configuration example of the solid-state imaging device 100-1 of the first embodiment according to the present technology, in which FIG. 12(a) is a plane layout view of the solid-state imaging device of the first embodiment, FIG. 12(b) is an enlarged plan view of an enlarged Q1 portion shown in FIG. 12(a), and FIG. 12(c) is a cross-sectional view for explaining an arrangement relationship between the low-reflection material 7 and the rib 1.

As shown in FIG. 1(a), the solid-state imaging device 100 is joined to the glass substrate 13 via the rib 1. A material forming the rib 1 is, for example, an epoxy resin.

As shown in FIG. 1(b), the low-reflection material 7 achieves prevention of reflection flare by covering a part of a light-shielding material 6 (for example, tungsten) to reduce reflection of light incident on the rib 1 by the light-shielding material 6. The rib 1 is formed outside a pixel array unit 200 and extends above the pixel array unit 200.

The low-reflection material 7 is formed by extending a blue filter 11 included in the pixel array unit to the left (to the left in FIG. 1(b)) to the outside of a region of the pixel array unit, so as to extend to a rib edge below the rib 1 (a lower side (middle) in FIG. 1). A first oxide film 5 is arranged on an upper side of the light-shielding material 6 (an upper side in FIG. 1(b)), and a second oxide film 12 is arranged in a left part of an upper side of the first oxide film 5 (the upper side in FIG. 1(b)) (a part on a left side in FIG. 1(b), in a direction toward the rib 1). In FIG. 1(b), a first organic material 2 is formed on an upper side of the low-reflection material 7 (the upper side in FIG. 1(b)), and the second oxide film 12 is arranged on an upper side of the first organic material 2 (the upper side in FIG. 1(b)). Furthermore, a second organic material 3 is formed on a lower side of the low-reflection material 7 (a lower side in FIG. 1(b)), and a semiconductor substrate 4 formed with a photodiode (not illustrated) is arranged below the second organic material 3 (the lower side in FIG. 1(b)).

Then, unless there is a particular technical contradiction, for the solid-state imaging device 100 described as FIG. 1, pieces of low-reflection 8, 9, 10, and 500 described later may be used instead of the low-reflection material 7.

A description will be given with reference to FIG. 2. The solid-state imaging device 100-1 includes: a rib 1 extending above (an upper side in FIG. 2, a light incident side) a pixel array unit (a first organic material 2 outside a pixel array unit region); a light-shielding material 6 (for example, tungsten) arranged below the rib 1 (a lower side in FIG. 2); and a low-reflection material 7 formed so as to cover at least a part of the light-shielding material 6. The low-reflection material 7 is, for example, a blue filter, and is formed below (the lower side in FIG. 2) and on a left side (a left side in FIG. 2) of the rib.

As shown in FIG. 2, even if light is incident on the rib 1, the low-reflection material 7 can prevent the light from being reflected.

FIG. 10 is a view for explaining that a width of the low-reflection material 7 can be changed freely in order to prevent light reflection and enhance the effect of preventing reflection flare, as described above. As shown in FIG. 10, in the low-reflection material 7, by changing the width of the low-reflection material 7 in a direction of arrow d1, the low-reflection material 7 may be formed on a left side of the rib 1, may be formed below the rib 1, or may be formed both on the left side and below the rib 1.

By freely changing the width (d1) of the low-reflection material 7, the low-reflection material 7 can further enhance the effect of preventing reflection flare.

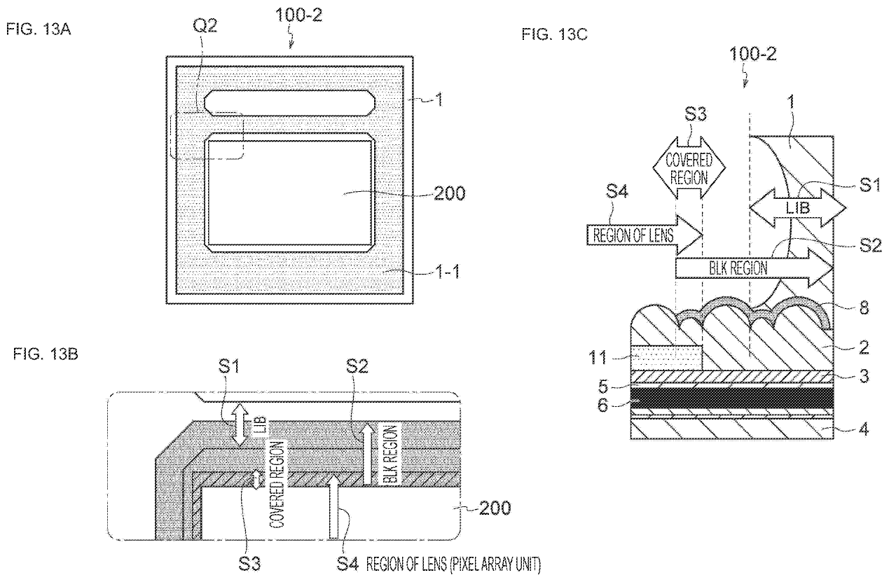

A description will be given with reference to FIG. 12. A region 1-1 shown in FIG. 12(a) is a region formed in an outer peripheral portion outside the pixel array unit 200, and is configured with at least the rib 1 and the light-shielding material 6. Then, only the rib 1 is formed in an outer peripheral portion outside of the region 1-1. Therefore, the solid-state imaging device 100-1 shown in FIG. 13(a) includes at least the pixel array unit 200, and the rib 1 and the light-shielding material 6 that are formed in the outer peripheral portion outside the pixel array unit 200.

As shown in FIGS. 12(b) and (c), the low-reflection material (the blue filter) 7 is formed extending to arrow R2. Then, a part of a region where the low-reflection material 7 is formed (arrow R2) is overlapped with a part of a region where the rib 1 is formed (arrow R1), and an overlap amount corresponds to formation the low-reflection material 7 entering under the rib 1. By this formation of the low-reflection material 7, the effect of preventing reflection flare is effectively exhibited.

For the solid-state imaging device of the first embodiment according to the present technology, in addition to the contents described above, contents described in a section of a solid-state imaging device of second to fifth embodiments according to the present technology described later can be applied as they are, as long as there is no particular technical contradiction.

### 3. Second Embodiment (Example 2 of Solid-State Imaging Device)

A solid-state imaging device of the second embodiment (Example 2 of a solid-state imaging device) according to the present technology is a solid-state imaging device including: a pixel array unit in which pixels having at least a photoelectric conversion unit configured to perform photoelectric conversion are arranged two-dimensionally; a rib formed in an outer peripheral portion outside the pixel array unit and extending above the pixel array unit; a light-shielding material arranged in an outer peripheral portion outside the pixel array unit and in at least a part of the pixel array unit, and further arranged below the rib; and a low-reflection material formed so as to cover at least a part of the light-shielding material. In the solid-state imaging device of the second embodiment according to the present technology, the low-reflection material may be any material that can suppress reflection of light. For example, examples include a material that absorbs light, an antireflection material, and the like. Specifically, examples include organic films such as color filters such as a blue filter that transmits blue light, a green filter that transmits green light, and a red filter that transmits red light, and a black filter. The low-reflection material included in the solid-state imaging device of the second embodiment according to the present technology is formed by forming a film on an organic material (for example, a lens material). In a case of a blue filter, a transmitted wavelength is a short wave length, which makes it possible to further suppress that light transmitted through the blue filter is reflected by the light-shielding material. Furthermore, a black filter is preferable because the black filter can absorb light in a wide wavelength band, transmits less light, and can suppress reflection by the light-shielding material. The low-reflection material may be formed below a rib, formed on a side of the rib, or formed below and on a side of the rib.

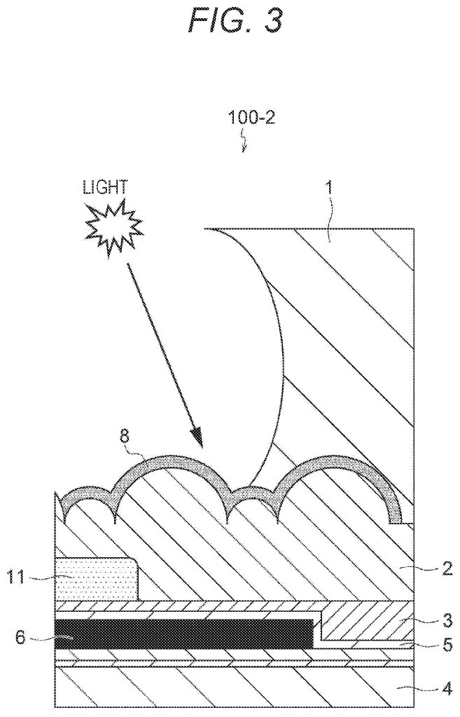

Hereinafter, with reference to FIGS. 3, 7, and 13, the solid-state imaging device of the second embodiment according to the present technology will be described.

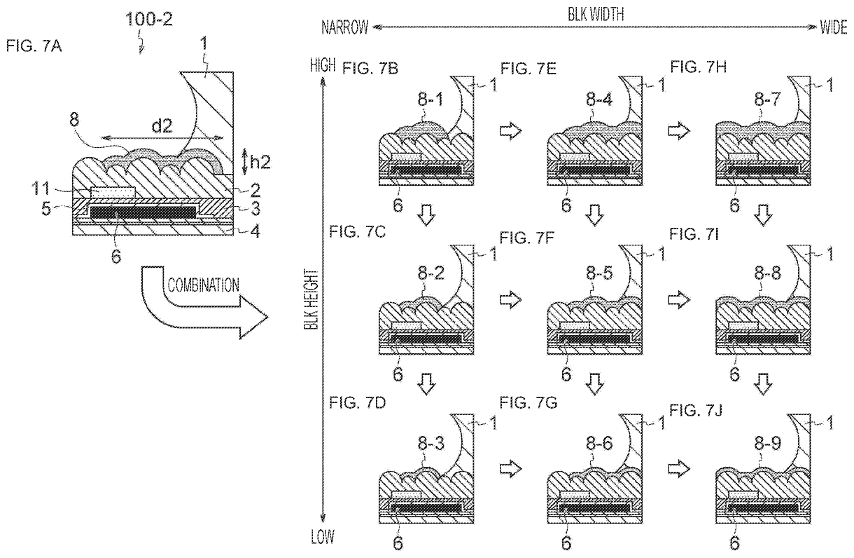

FIG. 3 is a cross-sectional view showing a configuration example of a solid-state imaging device 100-2 of the second embodiment according to the present technology. FIG. 7 is a view for explaining that a width and a height of a low-reflection material 8 can be changed freely in order to further enhance an effect of preventing reflection flare. FIG. 13 is a view showing a configuration example of the solid-state imaging device 100-2 of the second embodiment according to the present technology, in which FIG. 13(a) is a plane layout view of the solid-state imaging device of the second embodiment, FIG. 13(b) is an enlarged plan view of an enlarged Q2 portion shown in FIG. 13(a), and FIG. 13(c) is a cross-sectional view for explaining an arrangement relationship between a low-reflection material 8, a rib 1, and a pixel array unit 200 (a lens region).

A description will be given with reference to FIG. 3. The solid-state imaging device 100-2 includes: the rib 1 extending above (on an upper side in FIG. 3, a light incident side) the pixel array unit (a first organic material 2 outside a pixel array unit region); a light-shielding material 6 (for example, tungsten) arranged below the rib 1 (a lower side in FIG. 3); and the low-reflection material 8 formed so as to cover at least a part of the light-shielding material 6. The low-reflection material 8 is, for example, a black filter, formed below (the lower side in FIG. 3) and on a left side (a left side in FIG. 3) of the rib, and formed so as to be laminated on the first organic material 2 (the first organic material 2 in the pixel array unit is also referred to as a lens material).

As shown in FIG. 3, even if light is incident at the rib 1, the low-reflection material 8 can prevent the light from being reflected.

FIG. 7 is a view for explaining that a width and a height of the low-reflection material 8 can be changed freely in order to prevent light reflection and enhance the effect of preventing reflection flare, as described above. As shown in FIG. 7, in the low-reflection material 8, by changing the width of the low-reflection material 8 in the direction of arrow d2, the low-reflection material 8 may be formed on the left side of the rib 1, or may be formed on both the left side and the lower side of the rib 1 (FIG. 7(b) (a low-reflection material 8-1)→FIG. 7(e) (a low-reflection material 8-4)→FIG. 7(h) (a low-reflection material 8-7), FIG. 7(c) (a low-reflection material 8-2)→FIG. 7(f) (a low-reflection material 8-5)→FIG. 7(i) (a low-reflection material 8-8), or FIG. 7(d) (a low-reflection material 8-3)→FIG. 7(g) (a low-reflection material 8-6)→FIG. 7(j) (a low-reflection material 8-9)).

Furthermore, in the low-reflection material 8, the height of the low-reflection material 8 can be changed in a direction of arrow h2, that is, as shown in FIG. 7(b) (the low-reflection material 8-1)→FIG. 7(c) (the low-reflection material 8-2)→FIG. 7(d) (the low-reflection material 8-3), FIG. 7(e) (the low-reflection material 8-4)→FIG. 7(f) (the low-reflection material 8-5)→FIG. 7(g) (the low-reflection material 8-6), or FIG. 7(h) (the low-reflection material 8-7)→FIG. 7(i) (the low-reflection material 8-8)→FIG. 7(j) (the low-reflection material 8-9).

By freely changing the width (d2) and/or height (h2) of the low-reflection material 8, the low-reflection material 8 can further enhance the effect of preventing reflection flare.

A description will be given with reference to FIG. 13. A region 1-1 shown in FIG. 13(a) is a region formed in an outer peripheral portion outside the pixel array unit 200, and is configured with at least the rib 1 and the light-shielding material 6. Then, only the rib 1 is formed in an outer peripheral portion outside of the region 1-1. Therefore, the solid-state imaging device 100-2 shown in FIG. 13(a) includes at least the pixel array unit 200, and the rib 1 and the light-shielding material 6 that are formed in the outer peripheral portion outside the pixel array unit 200.

As shown in FIGS. 13(b) and (c), the low-reflection material (the black filter) 8 is formed up to arrow S2. Then, a part of a region where the low-reflection material 8 is formed (arrow S2) is overlapped with a part of a region where the rib 1 is formed (arrow S1), and an overlap amount corresponds to formation the low-reflection material 8 entering under the rib 1. Furthermore, a part of the region where the low-reflection material 8 is formed (arrow S2) is overlapped (a covered region S3) with a part of the pixel array unit (the lens region) 200, and the low-reflection material 8 is also formed in a part of the pixel array unit (lens region) 200. By this formation of the low-reflection material 8, the effect of preventing reflection flare is effectively exhibited.

For the solid-state imaging device of the second embodiment according to the present technology, in addition to the contents described above, the contents described in the section of the solid-state imaging device of the first embodiment according to the present technology described above and the contents described in the section of the solid-state imaging device of the third to fifth embodiments according to the present technology described below can be applied as they are, as long as there is no particular technical contradiction.

### 4. Third Embodiment (Example 3 of Solid-State Imaging Device)

A solid-state imaging device of the third embodiment (Example 3 of a solid-state imaging device) according to the present technology is a solid-state imaging device including: a pixel array unit in which pixels having at least a photoelectric conversion unit configured to perform photoelectric conversion are arranged two-dimensionally; a rib formed in an outer peripheral portion outside the pixel array unit and extending above the pixel array unit; a light-shielding material arranged at least in an outer peripheral portion outside the pixel array unit and further arranged below the rib; and a low-reflection material formed so as to cover at least a part of the light-shielding material. In the solid-state imaging device of the third embodiment according to the present technology, the low-reflection material may be any material that can suppress reflection of light. For example, examples include a material that absorbs light, an antireflection material, and the like. Specifically, examples include organic films such as color filters such as a blue filter that transmits blue light, a green filter that transmits green light, and a red filter that transmits red light, and a black filter. In a case where a color filter is used for the low-reflection material, formation at the same time in a process of forming an on-chip color filter of the pixel array unit is possible, which enables formation of the present embodiment without increasing the number of process steps. Especially in a case of a blue filter, a transmitted wavelength is a short wave length, which makes it possible to further suppress that light transmitted through the blue filter is reflected by the light-shielding material. Furthermore, a black filter is preferable because the black filter can absorb light in a wide wavelength band, transmits less light, and can suppress reflection by the light-shielding material. The low-reflection material may be formed below a rib, formed on a side of the rib, or formed below and on a side of the rib.

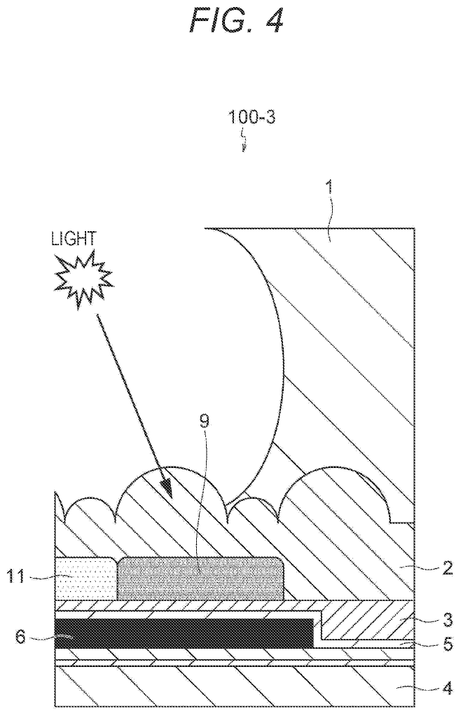

Hereinafter, with reference to FIGS. 4, 11, and 14, the solid-state imaging device of the third embodiment according to the present technology will be described.

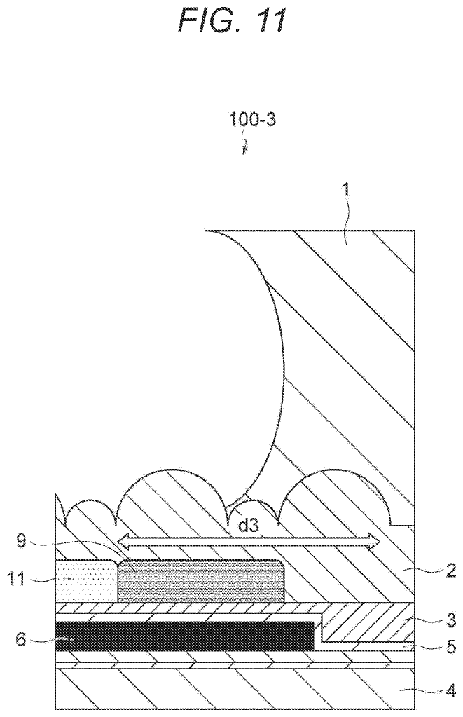

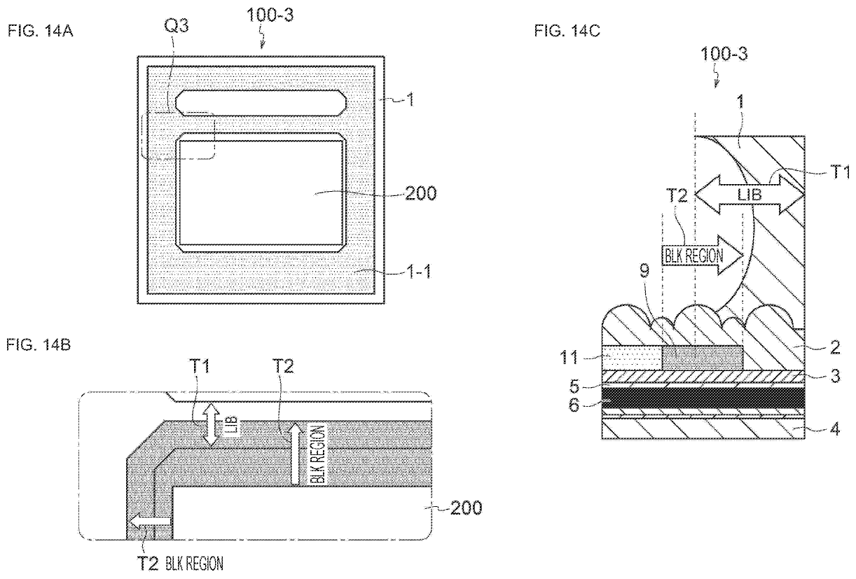

FIG. 4 is a cross-sectional view showing a configuration example of a solid-state imaging device 100-3 of the third embodiment according to the present technology. FIG. 11 is a view for explaining that a width of a low-reflection material 9 can be changed freely in order to further enhance an effect of preventing reflection flare. FIG. 14 is a view showing a configuration example of the solid-state imaging device 100-3 of the third embodiment according to the present technology, in which FIG. 14(a) is a plane layout view of the solid-state imaging device of the third embodiment, FIG. 14(b) is an enlarged plan view of an enlarged Q3 portion shown in FIG. 14(a), and FIG. 14(c) is a cross-sectional view for explaining an arrangement relationship between the low-reflection material 9 and a rib 1.

A description will be given with reference to FIG. 4. The solid-state imaging device 100-3 includes: the rib 1 extending above (on an upper side in FIG. 4, a light incident side) the pixel array unit (a first organic material 2 outside a pixel array unit region); a light-shielding material 6 (for example, tungsten) arranged below the rib 1 (a lower side in FIG. 4); and the low-reflection material 9 formed so as to cover at least a part of the light-shielding material 6. The low-reflection material 9 is, for example, a black filter, and is formed below (the lower side in FIG. 4) and on a left side (a left side in FIG. 4) of the rib.

As shown in FIG. 4, even if light is incident on the rib 1, the low-reflection material 9 can prevent the light from being reflected.

FIG. 11 is a view for explaining that a width of the low-reflection material 9 can be changed freely in order to prevent light reflection and enhance the effect of preventing reflection flare, as described above. As shown in FIG. 11, in the low-reflection material 9, by changing the width of the low-reflection material 9 in a direction of arrow d3, the low-reflection material 9 may be formed on the left side of the rib 1, may be formed below the rib 1, or may be formed both on the left side and below the rib 1.

By freely changing the width (d3) of the low-reflection material 9, the low-reflection material 9 can further enhance the effect of preventing reflection flare.

A description will be given with reference to FIG. 14. A region 1-1 shown in FIG. 14(a) is a region formed in an outer peripheral portion outside a pixel array unit 200, and is configured with at least the rib 1 and the light-shielding material 6. Then, only the rib 1 is formed in an outer peripheral portion outside of the region 1-1. Therefore, the solid-state imaging device 100-3 shown in FIG. 14(a) includes at least the pixel array unit 200, and the rib 1 and the light-shielding material 6 that are formed in the outer peripheral portion outside the pixel array unit 200.

As shown in FIGS. 13(b) and (c), the low-reflection material (the black filter) 9 is formed extending to arrow T2. Then, a part of a region where the low-reflection material 9 is formed (arrow T2) is overlapped with a part of a region where the rib 1 is formed (arrow T1), and an overlap amount corresponds to formation the low-reflection material 9 entering under the rib 1. By this formation of the low-reflection material 9, the effect of preventing reflection flare is effectively exhibited.

For the solid-state imaging device of the third embodiment according to the present technology, in addition to the contents described above, the contents described in the section of the solid-state imaging device of the first and second embodiments according to the present technology described above and the contents described in the section of the solid-state imaging device of the fourth and fifth embodiments according to the present technology described below can be applied as they are, as long as there is no particular technical contradiction.

### 5. Fourth Embodiment (Example 4 of Solid-State Imaging Device)

A solid-state imaging device of the fourth embodiment (Example 4 of a solid-state imaging device) according to the present technology is a solid-state imaging device including: a pixel array unit in which pixels having at least a photoelectric conversion unit configured to perform photoelectric conversion are arranged two-dimensionally; a rib formed in an outer peripheral portion outside the pixel array unit and extending above the pixel array unit; a light-shielding material arranged at least in an outer peripheral portion outside the pixel array unit and further arranged below the rib; and a low-reflection material formed so as to cover at least a part of the light-shielding material. In the solid-state imaging device of the fourth embodiment according to the present technology, the low-reflection material may be any material that can suppress reflection of light. For example, examples include a material that absorbs light, an antireflection material, and the like. Specifically, examples include organic films such as color filters such as a blue filter that transmits blue light, a green filter that transmits green light, and a red filter that transmits red light, and a black filter. In a case where a color filter is used for the low-reflection material, formation at the same time in a process of forming an on-chip color filter of the pixel array unit is possible, which enables formation of the present embodiment without increasing the number of process steps. Especially in a case of a blue filter, a transmitted wavelength is a short wave length, which makes it possible to further suppress that light transmitted through the blue filter is reflected by the light-shielding material. Furthermore, a black filter is preferable because the black filter can absorb light in a wide wavelength band, transmits less light, and can suppress reflection by the light-shielding material. The low-reflection material may be formed below a rib, formed on a side of the rib, or formed below and on a side of the rib.

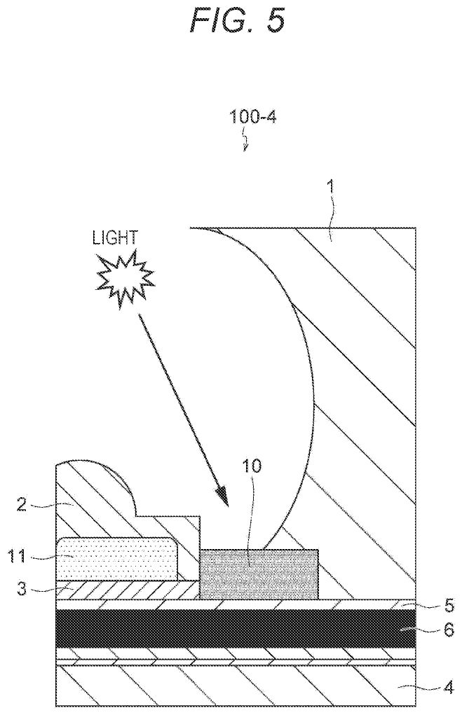

Hereinafter, with reference to FIGS. 5, 8, and 15, the solid-state imaging device of the fourth embodiment according to the present technology will be described.

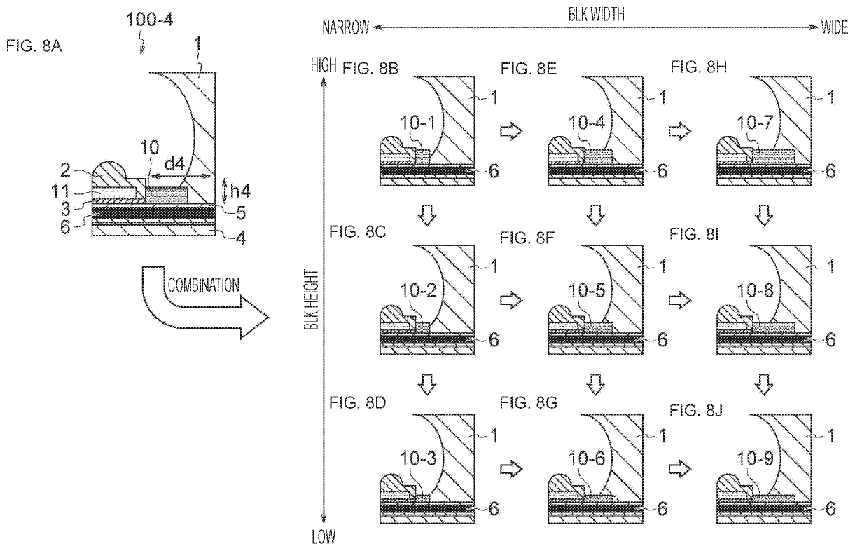

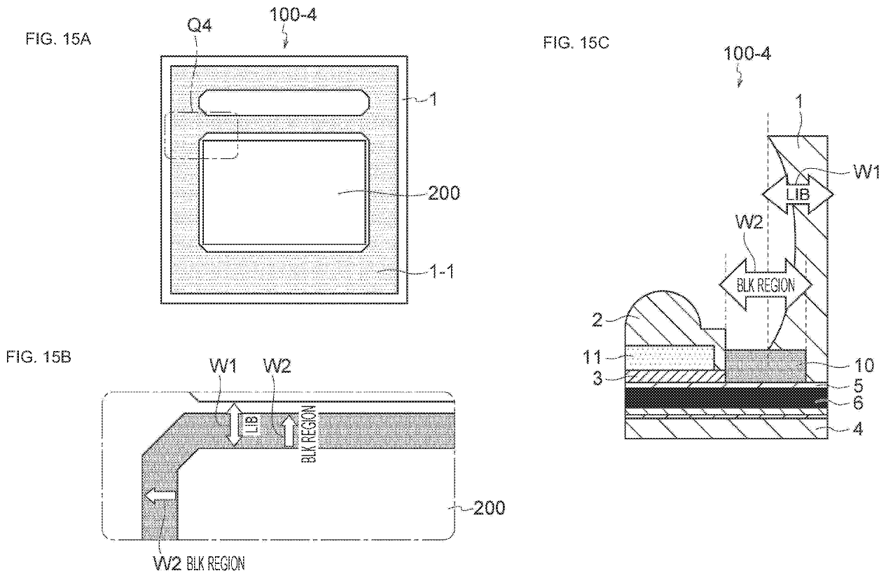

FIG. 5 is a cross-sectional view showing a configuration example of a solid-state imaging device 100-4 of the fourth embodiment according to the present technology. FIG. 8 is a view for explaining that a width and a height of a low-reflection material 10 can be changed freely in order to further enhance an effect of preventing reflection flare. FIG. 15 is a view showing a configuration example of the solid-state imaging device 100-4 of the third embodiment according to the present technology, in which FIG. 15(a) is a plane layout view of the solid-state imaging device of the fourth embodiment, FIG. 15(b) is an enlarged plan view of an enlarged Q4 portion shown in FIG. 15(a), and FIG. 15(c) is a cross-sectional view for explaining an arrangement relationship between the low-reflection material 10 and a rib 1.

A description will be given with reference to FIG. 5. The solid-state imaging device 100-4 includes: the rib 1 extending above (on an upper side in FIG. 5, a light incident side) the pixel array unit (a first organic material 2 outside a pixel array unit region); a light-shielding material 6 (for example, tungsten) arranged below the rib 1 (a lower side in FIG. 5); and the low-reflection material 10 formed so as to cover at least a part of the light-shielding material 6. The low-reflection material 10 is, for example, a black filter, and is formed below (the lower side in FIG. 3) and on a left side (a left side in FIG. 3) of the rib, and laminated on a light-shielding material 6 via a first oxide film 5.

As shown in FIG. 5, even if light is incident at the rib 1, the low-reflection material 10 can prevent the light from being reflected.

FIG. 8 is a view for explaining that a width and a height of the low-reflection material 10 can be changed freely in order to prevent light reflection and enhance the effect of preventing reflection flare, as described above. As shown in FIG. 8, in the low-reflection material 10, by changing the width of the low-reflection material 10 in the direction of arrow d4, the low-reflection material 10 may be formed on the left side of the rib 1, or may be formed on both the left side and the lower side of the rib 1 (FIG. 8(b) (a low-reflection material 10-1)→FIG. 8(e) (a low-reflection material 10-4)→FIG. 8(h) (a low-reflection material 10-7), FIG. 8(c) (a low-reflection material 10-2)→FIG. 8(f) (a low-reflection material 10-5)→FIG. 8(i) (a low-reflection material 10-8), or FIG. 8(d) (a low-reflection material 10-3)→FIG. 8(g) (a low-reflection material 10-6)→FIG. 8(j) (a low-reflection material 10-9)).

Furthermore, in the low-reflection material 10, the height of the low-reflection material 10 can be changed in a direction of arrow h4, that is, as shown in FIG. 8(b) (the low-reflection material 10-1)→FIG. 8(c) (the low-reflection material 10-2)→FIG. 8(d) (the low-reflection material 10-3), FIG. 8(e) (the low-reflection material 10-4)→FIG. 8(f) (the low-reflection material 10-5)→FIG. 8(g) (the low-reflection material 10-6), or FIG. 8(h) (the low-reflection material 10-7)→FIG. 8(i) (the low-reflection material 10-8)→FIG. 8(j) (the low-reflection material 10-9).

By freely changing the width (d4) and/or height (h4) of the low-reflection material 10, the low-reflection material 10 can further enhance the effect of preventing reflection flare.

A description will be given with reference to FIG. 15. A region 1-1 shown in FIG. 15(a) is a region formed in an outer peripheral portion outside a pixel array unit 200, and is configured with at least the rib 1 and the light-shielding material 6. Then, only the rib 1 is formed in an outer peripheral portion outside of the region 1-1. Therefore, the solid-state imaging device 100-4 shown in FIG. 15(a) includes at least the pixel array unit 200, and the rib 1 and the light-shielding material 6 that are formed in the outer peripheral portion outside the pixel array unit 200.

As shown in FIGS. 15(b) and (c), the low-reflection material (the black filter) 10 is formed up to a region of arrow W2. Then, a part of a region where the low-reflection material 10 is formed (arrow W2) is overlapped with a part of a region where the rib 1 is formed (arrow W1), and an overlap amount corresponds to formation the low-reflection material 10 entering under the rib 1. By this formation of the low-reflection material 10, the effect of preventing reflection flare is effectively exhibited.

For the solid-state imaging device of the fourth embodiment according to the present technology, in addition to the contents described above, the contents described in the section of the solid-state imaging device of the first to third embodiments according to the present technology described above and the contents described in the section of the solid-state imaging device of the fifth embodiment according to the present technology described below can be applied as they are, as long as there is no particular technical contradiction.

### 6. Fifth Embodiment (Example 5 of Solid-State Imaging Device)

A solid-state imaging device of the fifth embodiment (Example 5 of a solid-state imaging device) according to the present technology is a solid-state imaging device including: a pixel array unit in which pixels having at least a photoelectric conversion unit configured to perform photoelectric conversion are arranged two-dimensionally; a rib formed in an outer peripheral portion outside the pixel array unit and extending above the pixel array unit; a light-shielding material arranged in an outer peripheral portion outside the pixel array unit and in at least a part of the pixel array unit, and further arranged below the rib; and a low-reflection material formed so as to cover at least a part of the light-shielding material. In the solid-state imaging device of the fifth embodiment according to the present technology, the low-reflection material may be any material that can suppress reflection of light. For example, examples include a material that absorbs light, an antireflection material, and the like. Specifically, examples include organic films such as color filters such as a blue filter that transmits blue light, a green filter that transmits green light, and a red filter that transmits red light, and a black filter. The low-reflection material included in the solid-state imaging device of the fifth embodiment according to the present technology is formed by uniformly forming a film on a flattened organic material (for example, a lens material). The low-reflection material included in the solid-state imaging device of the fifth embodiment according to the present technology can ensure uniformity of a film thickness. In a case where a color filter is used for the low-reflection material, formation at the same time in a process of forming an on-chip color filter of the pixel array unit is possible, which enables formation of the present embodiment without increasing the number of process steps. Especially in a case of a blue filter, a transmitted wavelength is a short wave length, which makes it possible to further suppress that light transmitted through the blue filter is reflected by the light-shielding material. Furthermore, a black filter is preferable because the black filter can absorb light in a wide wavelength band, transmits less light, and can suppress reflection by the light-shielding material. The low-reflection material may be formed below a rib, formed on a side of the rib, or formed below and on a side of the rib.

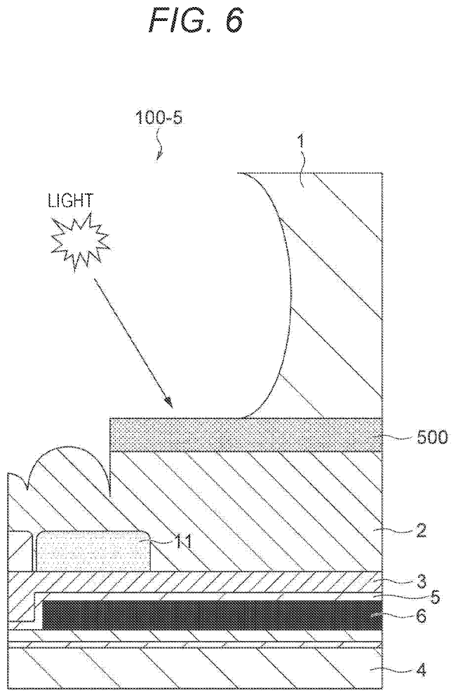

Hereinafter, with reference to FIGS. 6, 9, and 16, the solid-state imaging device of the fifth embodiment according to the present technology will be described.

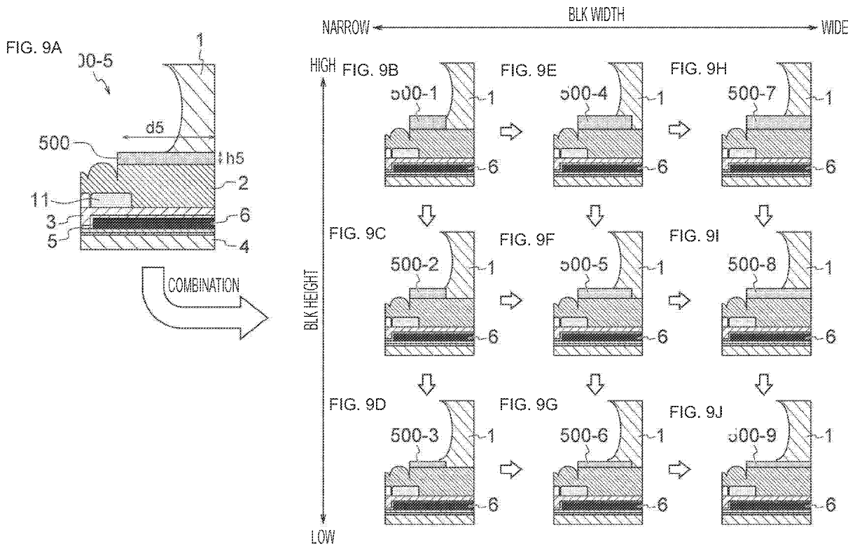

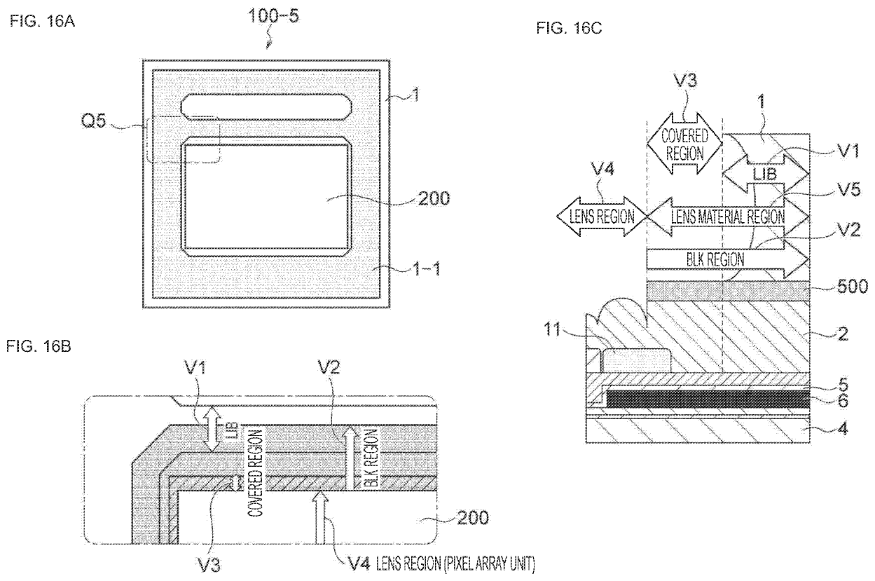

FIG. 6 is a cross-sectional view showing a configuration example of a solid-state imaging device 500 of the fifth embodiment according to the present technology. FIG. 9 is a view for explaining that a width and a height of a low-reflection material 500 can be changed freely in order to further enhance an effect of preventing reflection flare. FIG. 16 is a view showing a configuration example of the solid-state imaging device 100-5 of the fifth embodiment according to the present technology, in which FIG. 16(a) is a plane layout view of the solid-state imaging device of the fifth embodiment, FIG. 16(b) is an enlarged plan view of an enlarged Q5 portion shown in FIG. 16(a), and FIG. 16(c) is a cross-sectional view for explaining an arrangement relationship between the low-reflection material 500, a rib 1, and a pixel array unit 200 (a lens region).

A description will be given with reference to FIG. 6. The solid-state imaging device 100-5 includes: the rib 1 extending above (on an upper side in FIG. 6, a light incident side) the pixel array unit (a first organic material 2 outside a pixel array unit region); a light-shielding material 6 (for example, tungsten) arranged below the rib 1 (a lower side in FIG. 6); and the low-reflection material 500 formed so as to cover at least a part of the light-shielding material 6. The low-reflection material 500 is, for example, a black filter, and is formed below (the lower side in FIG. 6) and on a left side (a left side in FIG. 6) of the rib, and formed so as to be laminated on the flattened first organic material 2 while ensuring uniformity of a film thickness of the low-reflection material 500.

As shown in FIG. 6, even if light is incident at the rib 1, the low-reflection material 500 can prevent the light from being reflected.

FIG. 9 is a view for explaining that a width and a height of the low-reflection material 500 can be changed freely in order to prevent light reflection and enhance the effect of preventing reflection flare, as described above. As shown in FIG. 9, in the low-reflection material 500, by changing the width of the low-reflection material 500 in the direction of arrow d5, the low-reflection material 500 may be formed on the left side of the rib 1, or may be formed on both the left side and the lower side of the rib 1 (FIG. 9(b) (a low-reflection material 500-1)→FIG. 9(e) (a low-reflection material 500-4)→FIG. 9(h) (a low-reflection material 500-7), FIG. 9(c) (a low-reflection material 500-2)→FIG. 9(f) (a low-reflection material 500-5)→FIG. 9(i) (a low-reflection material 500-8), or FIG. 9(d) (a low-reflection material 500-2)→FIG. 9(g) (a low-reflection material 500-6)→FIG. 9(j) (a low-reflection material 500-9)).

Furthermore, in the low-reflection material 500, the height (a film thickness) of the low-reflection material 500 can be changed in a direction of arrow h5, that is, as shown in FIG. 9(b) (the low-reflection material 500-1)→FIG. 9(c) (the low-reflection material 500-2)→FIG. 9(d) (the low-reflection material 500-3), FIG. 9(e) (the low-reflection material 500-4)→FIG. 9(f) (the low-reflection material 500-5)→FIG. 9(g) (the low-reflection material 500-6), or FIG. 9(h) (the low-reflection material 500-7)→FIG. 9(i) (the low-reflection material 500-8)→FIG. 9(j) (the low-reflection material 500-9).

By freely changing the width (d5) and/or height (h5) of the low-reflection material 500, the low-reflection material 500 can further enhance the effect of preventing reflection flare.

A description will be given with reference to FIG. 16. A region 1-1 shown in FIG. 16(a) is a region formed in an outer peripheral portion outside the pixel array unit 200, and is configured with at least the rib 1 and the light-shielding material 6. Then, only the rib 1 is formed in an outer peripheral portion outside of the region 1-1. Therefore, the solid-state imaging device 100-5 shown in FIG. 16(a) includes at least the pixel array unit 200, and the rib 1 and the light-shielding material 6 that are formed in the outer peripheral portion outside the pixel array unit 200.

As shown in FIGS. 16(b) and (c), the low-reflection material (the black filter) 500 is formed to have a substantially uniform film thickness up to arrow V2. Then, a part of a region where the low-reflection material 500 is formed (arrow V2) is overlapped with a part of a region where the rib 1 is formed (arrow V1), and an overlap amount corresponds to formation the low-reflection material 500 entering under the rib 1. Furthermore, the region where the low-reflection material 500 is formed (arrow V2) and a region where the lens material (the first organic material 2) is formed (arrow V5) substantially coincide with each other. The region where the low-reflection material 500 is formed (arrow V2) and the pixel array unit (the lens region) 200 (arrow V4) do not overlap. There is a covered region (arrow V3) between the pixel array unit (the lens region) 200 (arrow V4) and the region where the rib 1 is formed (arrow V1), and the covered region (arrow V3) is overlapped with a part of the region where the low-reflection material 500 is formed (arrow V2) or a part of the region where the lens material (the first organic material 2) is formed (arrow V5). By this formation of the low-reflection material 500, the effect of preventing reflection flare is effectively exhibited.

For the solid-state imaging device of the fifth embodiment according to the present technology, in addition to the contents described above, contents described in the section of the solid-state imaging device of the first to fourth embodiments according to the present technology described above can be applied as they are, as long as there is no particular technical contradiction.

### 7. Sixth Embodiment (Example of Electronic Device)

An electronic device of a sixth embodiment according to the present technology is an electronic device equipped with the solid-state imaging device of any one of the solid-state imaging devices of the first to fifth embodiments according to the present technology. Hereinafter, the electronic device of the sixth embodiment according to the present technology will be described in detail.

### 8. Usage Example of Solid-State Imaging Device to which Present Technology is Applied

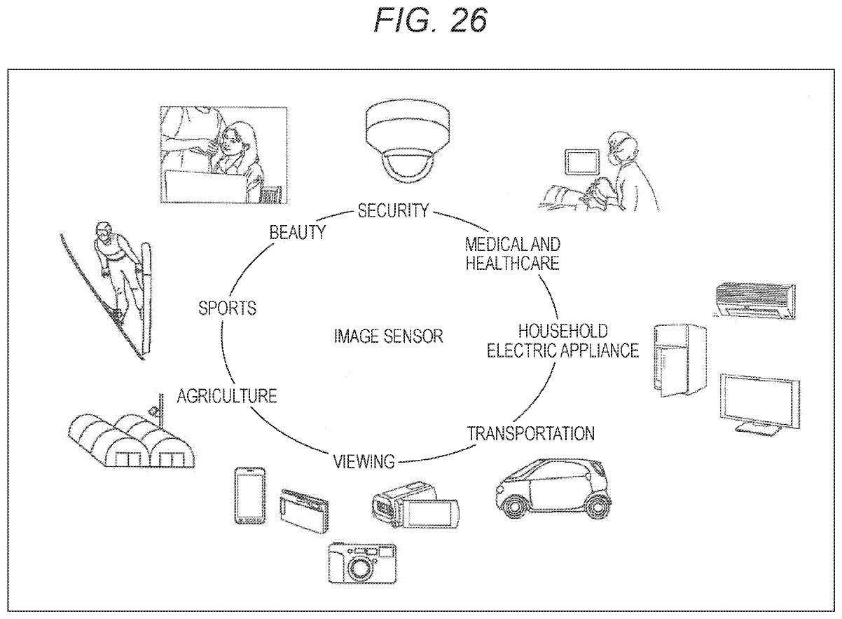

FIG. 26 is a view showing a usage example, as an image sensor, of the solid-state imaging device of the first to fifth embodiments according to the present technology.

The solid-state imaging device of the first to fifth embodiments described above can be used in various cases for sensing light such as visible light, infrared light, ultraviolet light, and X-ray, as described below, for example. That is, as shown in FIG. 26, the solid-state imaging device of any one of the first to fifth embodiments can be used for devices (for example, the electronic device of the sixth embodiment described above) used in, for example, a field of viewing where images to be used for viewing are captured, a field of transportation, a field of household electric appliances, a field of medical and healthcare, a field of security, a field of beauty care, a field of sports, a field of agriculture, and the like.

Specifically, in the field of viewing, the solid-state imaging device of any one of the first to fifth embodiments can be used for devices to capture an image to be used for viewing, for example, such as a digital camera, a smartphone, or a mobile phone with a camera function.

In the field of transportation, for example, for safe driving such as automatic stop, recognition of a state of a driver, and the like, the solid-state imaging device of any one of the first to fifth embodiments can be used for devices used for transportation, such as vehicle-mounted sensors that capture an image in front, rear, surroundings, interior, and the like of an automobile, monitoring cameras that monitor traveling vehicles and roads, and distance measurement sensors that measure a distance between vehicles.

In the field of household electric appliances, for example, in order to capture an image of a user's gesture and operate a device in accordance with the gesture, the solid-state imaging device of any one of the first to fifth embodiments can be used for devices used in household electric appliances such as TV receivers, refrigerators, and air conditioners.

In the field of medical and healthcare, for example, the solid-state imaging device of any one of the first to fifth embodiments can be used for devices used for medical and healthcare, such as endoscopes and devices that perform angiography by receiving infrared light.

In the field of security, for example, the solid-state imaging device of any one of the first to fifth embodiments can be used for devices used for security such as monitoring cameras for crime prevention and cameras for personal authentication.

In the field of beauty care, for example, the solid-state imaging device of any one of the first to fifth embodiments can be used for devices used for beauty care such as skin measuring instruments for image capturing of skin, and microscopes for image capturing of a scalp.

In the field of sports, for example, the solid-state imaging device of any one of the first to fifth embodiments can be used for devices used for sports such as action cameras and wearable cameras for sports applications and the like.

In the field of agriculture, for example, the solid-state imaging device of any one of the first to fifth embodiments can be used for devices used for agriculture such as cameras for monitoring conditions of fields and crops.

The solid-state imaging device according to any one of the first to fifth embodiments can be applied to various electronic devices such as, for example, an imaging device such as a digital still camera and a digital video camera, a mobile phone with an imaging function, or other devices having an imaging function.

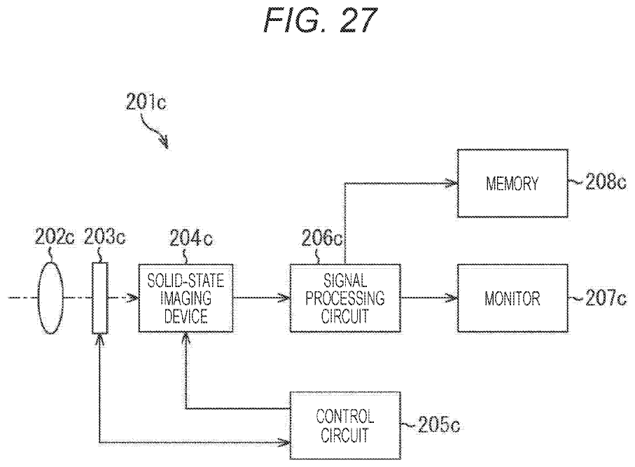

FIG. 27 is a block diagram showing a configuration example of an imaging device as an electronic device to which the present technology is applied.

An imaging device 201c shown in FIG. 27 includes an optical system 202c, a shutter device 203c, a solid-state imaging device 204c, a drive circuit 205c, a signal processing circuit 206c, a monitor 207c, and a memory 208c, and can capture still images and moving images.

The optical system 202c has one or more lenses, and guides light (incident light) from a subject to the solid-state imaging device 204c and forms as an image on a light receiving surface of the solid-state imaging device 204c.

The shutter device 203c is arranged between the optical system 202c and the solid-state imaging device 204c, and controls a light irradiation period and a shading period of the solid-state imaging device 204c in accordance with the control of the control circuit 205c.

The solid-state imaging device 204c accumulates signal charges for a certain period of time in accordance with light formed as an image on the light receiving surface via the optical system 202c and the shutter device 203c. The signal charges accumulated in the solid-state imaging device 204c are transferred in accordance with a drive signal (a timing signal) supplied from the control circuit 205c.

The control circuit 205c outputs a drive signal for controlling a transfer operation of the solid-state imaging device 204c and a shutter operation of the shutter device 203c, to drive the solid-state imaging device 204c and the shutter device 203c.

The signal processing circuit 206c performs various kinds of signal processing on the signal charges outputted from the solid-state imaging device 204c. An image (image data) obtained by performing signal processing by the signal processing circuit 206c is supplied to the monitor 207c to be displayed, or supplied to the memory 208c to be stored (recorded).

### 9. Application Example to Endoscopic Surgery System

The present technology can be applied to various products. For example, the technology (the present technology) according to the present disclosure may be applied to an endoscopic surgery system.

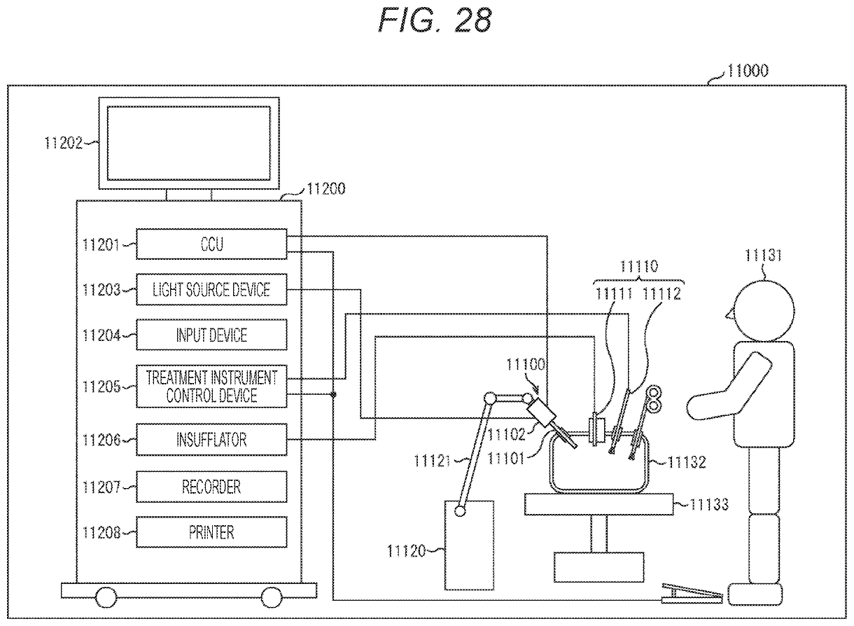

FIG. 28 is a diagram showing an example of a schematic configuration of an endoscopic surgery system to which the technology (the present technology) according to the present disclosure can be applied.

FIG. 28 illustrates a state where an operator (a doctor) 11131 performs surgery on a patient 11132 on a patient bed 11133, by using an endoscopic surgery system 11000. As illustrated, the endoscopic surgery system 11000 includes: an endoscope 11100; other surgical instruments 11110 such as an insufflation tube 11111 and an energy treatment instrument 11112; a support arm device 11120 supporting the endoscope 11100; and a cart 11200 mounted with various devices for endoscopic surgery.

The endoscope 11100 includes a lens barrel 11101 whose region of a predetermined length from a distal end is inserted into a body cavity of the patient 11132, and a camera head 11102 connected to a proximal end of the lens barrel 11101. In the illustrated example, the endoscope 11100 configured as a so-called rigid endoscope having a rigid lens barrel 11101 is illustrated, but the endoscope 11100 may be configured as a so-called flexible endoscope having a flexible lens barrel.

At the distal end of the lens barrel 11101, an opening fitted with an objective lens is provided. The endoscope 11100 is connected with a light source device 11203, and light generated by the light source device 11203 is guided to the distal end of the lens barrel by a light guide extended inside the lens barrel 11101, and emitted toward an observation target in the body cavity of the patient 11132 through the objective lens. Note that the endoscope 11100 may be a forward-viewing endoscope, or may be an oblique-viewing endoscope or a side-viewing endoscope.

Inside the camera head 11102, an optical system and an imaging element are provided, and reflected light (observation light) from the observation target is condensed on the imaging element by the optical system. The observation light is photoelectrically converted by the imaging element, and an electric signal corresponding to the observation light, in other words, an image signal corresponding to an observation image is generated. The image signal is transmitted to a camera control unit (CCU) 11201 as RAW data.

The CCU 11201 is configured by a central processing unit (CPU), a graphics processing unit (GPU), and the like, and integrally controls action of the endoscope 11100 and a display device 11202. Moreover, the CCU 11201 receives an image signal from the camera head 11102, and applies, on the image signal, various types of image processing for displaying an image on the basis of the image signal, for example, development processing (demosaicing processing) and the like.

The display device 11202 displays an image on the basis of the image signal subjected to the image processing by the CCU 11201, under the control of the CCU 11201.

The light source device 11203 is configured by a light source such as a light emitting diode (LED), for example, and supplies irradiation light at a time of capturing an image of the operative site or the like to the endoscope 11100.

An input device 11204 is an input interface to the endoscopic surgery system 11000. A user can input various types of information and input instructions to the endoscopic surgery system 11000 via the input device 11204. For example, the user inputs an instruction or the like for changing imaging conditions (a type of irradiation light, a magnification, a focal length, and the like) by the endoscope 11100.

A treatment instrument control device 11205 controls driving of the energy treatment instrument 11112 for ablation of a tissue, incision, sealing of a blood vessel, or the like. An insufflator 11206 sends gas into a body cavity through the insufflation tube 11111 in order to inflate the body cavity of the patient 11132 for the purpose of securing a visual field by the endoscope 11100 and securing a working space of the operator. A recorder 11207 is a device capable of recording various types of information regarding the surgery. A printer 11208 is a device capable of printing various types of information regarding the surgery in various forms such as text, images, and graphs.

Note that the light source device 11203 that supplies the endoscope 11100 with irradiation light for capturing an image of the operative site may include, for example, a white light source configured by an LED, a laser light source, or a combination thereof. In a case where the white light source is configured by a combination of RGB laser light sources, since output intensity and output timing of each color (each wavelength) can be controlled with high precision, the light source device 11203 can adjust white balance of a captured image. Furthermore, in this case, it is also possible to capture an image corresponding to each of RGB in a time division manner by irradiating the observation target with laser light from each of the RGB laser light sources in a time-division manner, and controlling driving of the imaging element of the camera head 11102 in synchronization with the irradiation timing. According to this method, it is possible to obtain a color image without providing a color filter in the imaging element.

Furthermore, driving of the light source device 11203 may be controlled to change intensity of the light to be outputted at every predetermined time interval. By acquiring images in a time-division manner by controlling the driving of the imaging element of the camera head 11102 in synchronization with the timing of the change of the light intensity, and combining the images, it is possible to generate an image of a high dynamic range without so-called black defects and whiteout.

Furthermore, the light source device 11203 may be configured to be able to supply light having a predetermined wavelength band corresponding to special light observation. In the special light observation, for example, so-called narrow band imaging is performed in which predetermined tissues such as blood vessels in a mucous membrane surface layer are imaged with high contrast by utilizing wavelength dependency of light absorption in body tissues and irradiating the predetermined tissues with narrow band light as compared to the irradiation light (in other words, white light) at the time of normal observation. Alternatively, in the special light observation, fluorescence observation for obtaining an image by fluorescence generated by irradiation of excitation light may be performed. In the fluorescence observation, it is possible to perform irradiating a body tissue with excitation light and observing fluorescence from the body tissue (autofluorescence observation), locally injecting a reagent such as indocyanine green (ICG) into a body tissue and irradiating the body tissue with excitation light corresponding to the fluorescence wavelength of the reagent to obtain a fluorescent image, or the like. The light source device 11203 may be configured to be able to supply narrow band light and/or excitation light corresponding to such special light observation.

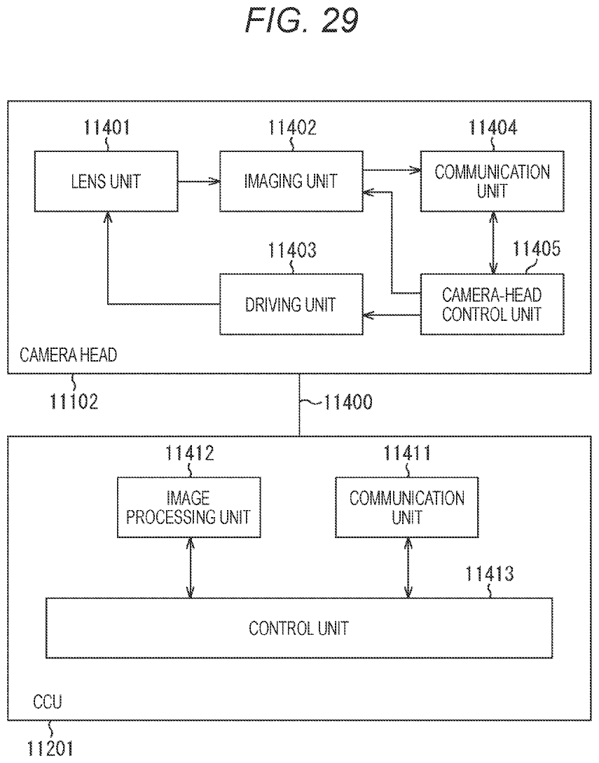

FIG. 29 is a block diagram showing an example of a functional configuration of the camera head 11102 and the CCU 11201 shown in FIG. 28.

The camera head 11102 has a lens unit 11401, an imaging unit 11402, a driving unit 11403, a communication unit 11404, and a camera-head control unit 11405. The CCU 11201 has a communication unit 11411, an image processing unit 11412, and a control unit 11413. The camera head 11102 and the CCU 11201 are communicably connected in both directions by a transmission cable 11400.

The lens unit 11401 is an optical system provided at a connection part with the lens barrel 11101. Observation light taken in from the distal end of the lens barrel 11101 is guided to the camera head 11102 and is incident on the lens unit 11401. The lens unit 11401 is configured by combining a plurality of lenses including a zoom lens and a focus lens.

The imaging unit 11402 is configured with an imaging device (an imaging element). The number of the imaging elements included in the imaging unit 11402 may be one (a so-called single plate type) or plural (a so-called multi-plate type). In a case where the imaging unit 11402 is configured with the multi-plate type, for example, individual imaging elements may generate image signals corresponding to RGB each, and a color image may be obtained by synthesizing them. Alternatively, the imaging unit 11402 may have a pair of imaging elements for respectively acquiring image signals for the right eye and the left eye corresponding to three-dimensional (3D) display. Performing 3D display enables the operator 11131 to more accurately grasp a depth of living tissues in the operative site. Note that, in a case where the imaging unit 11402 is configured as the multi-plate type, a plurality of systems of the lens unit 11401 may also be provided corresponding to individual imaging elements.

Furthermore, the imaging unit 11402 may not necessarily be provided in the camera head 11102. For example, the imaging unit 11402 may be provided inside the lens barrel 11101 immediately after the objective lens.

The driving unit 11403 is configured by an actuator, and moves the zoom lens and the focus lens of the lens unit 11401 along an optical axis by a predetermined distance under control from the camera-head control unit 11405. With this configuration, a magnification and focus of a captured image by the imaging unit 11402 may be appropriately adjusted.

The communication unit 11404 is configured by a communication device for exchange of various types of information between with the CCU 11201. The communication unit 11404 transmits an image signal obtained from the imaging unit 11402 to the CCU 11201 via the transmission cable 11400 as RAW data.

Furthermore, the communication unit 11404 receives a control signal for controlling driving of the camera head 11102 from the CCU 11201, and supplies to the camera-head control unit 11405. The control signal includes information regarding imaging conditions such as, for example, information of specifying a frame rate of a captured image, information of specifying an exposure value at the time of imaging, information of specifying a magnification and focus of a captured image, and/or the like.

Note that the imaging conditions described above such as a frame rate, an exposure value, magnification, and focus may be appropriately specified by the user, or may be automatically set by the control unit 11413 of the CCU 11201 on the basis of the acquired image signal. In the latter case, a so-called auto exposure (AE) function, auto focus (AF) function, and auto white balance (AWB) function are to be installed in the endoscope 11100.

The camera-head control unit 11405 controls driving of the camera head 11102 on the basis of the control signal from the CCU 11201 received via the communication unit 11404.

The communication unit 11411 is configured by a communication device for exchange of various types of information with the camera head 11102. The communication unit 11411 receives an image signal transmitted via the transmission cable 11400 from the camera head 11102.

Furthermore, the communication unit 11411 transmits, to the camera head 11102, a control signal for controlling driving of the camera head 11102. Image signals and control signals can be transmitted by telecommunication, optical communication, or the like.

The image processing unit 11412 performs various types of image processing on an image signal that is RAW data transmitted from the camera head 11102.

The control unit 11413 performs various types of control related to imaging of an operative site and the like by the endoscope 11100 and related to display of a captured image obtained by the imaging of the operative site and the like. For example, the control unit 11413 generates a control signal for controlling driving of the camera head 11102.

Furthermore, the control unit 11413 causes the display device 11202 to display a captured image in which the operative site or the like is shown, on the basis of the image signal subjected to the image processing by the image processing unit 11412. At this time, the control unit 11413 recognizes various objects in the captured image by using various image recognition techniques. For example, by detecting a shape, a color, and the like of an edge of the object included in the captured image, the control unit 11413 can recognize a surgical instrument such as forceps, a specific living site, bleeding, mist in using the energy treatment instrument 11112, and the like. When causing the display device 11202 to display the captured image, the control unit 11413 may use the recognition result to superimpose and display various types of surgery support information on the image of the operative site. By superimposing and displaying the surgical support information and presenting to the operator 11131, it becomes possible to reduce a burden on the operator 11131 and to allow the operator 11131 to reliably proceed with the surgery.

The transmission cable 11400 connecting the camera head 11102 and the CCU 11201 is an electric signal cable corresponding to communication of an electric signal, an optical fiber corresponding to optical communication, or a composite cable of these.

Here, in the illustrated example, communication is performed by wire communication using the transmission cable 11400, but communication between the camera head 11102 and the CCU 11201 may be performed wirelessly.

An example of the endoscopic surgery system to which the technology according to the present disclosure can be applied has been described above. The technology according to the present disclosure can be applied to the endoscope 11100, (the imaging unit 11402 of) the camera head 11102, and the like among the configurations described above. Specifically, a solid-state imaging device 111 of the present disclosure can be applied to the imaging unit 10402. By applying the technology according to the present disclosure to the endoscope 11100, (the imaging unit 11402 of) the camera head 11102, and the like, performance can be improved.

Here, the endoscopic surgery system has been described as an example, but the technology according to the present disclosure may be applied to other, for example, a microscopic surgery system or the like.

### 10. Application Example to Mobile Object

The technology (the present technology) according to the present disclosure can be applied to various products. For example, the technology according to the present disclosure may be realized as a device equipped on any type of mobile objects, such as an automobile, an electric car, a hybrid electric car, a motorcycle, a bicycle, personal mobility, an airplane, a drone, a ship, a robot, and the like.

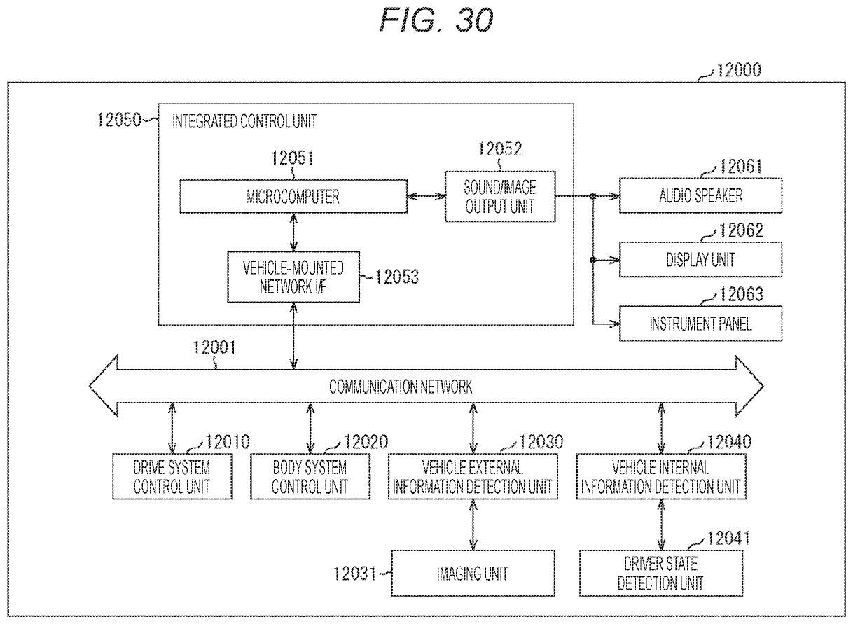

FIG. 30 is a block diagram showing a schematic configuration example of a vehicle control system, which is an example of a mobile object control system to which the technology according to the present disclosure may be applied.

A vehicle control system 12000 includes a plurality of electronic control units connected via a communication network 12001. In the example shown in FIG. 30, the vehicle control system 12000 includes a drive system control unit 12010, a body system control unit 12020, a vehicle external information detection unit 12030, a vehicle internal information detection unit 12040, and an integrated control unit 12050. Furthermore, as a functional configuration of the integrated control unit 12050, a microcomputer 12051, a sound/image output unit 12052, and a vehicle-mounted network interface (I/F) 12053 are illustrated.

The drive system control unit 12010 controls an operation of devices related to a drive system of a vehicle in accordance with various programs. For example, the drive system control unit 12010 functions as: a driving force generation device for generation of a driving force of the vehicle such as an internal combustion engine or a drive motor; a driving force transmission mechanism for transmission of a driving force to wheels; a steering mechanism to adjust a steering angle of the vehicle; and a control device such as a braking device that generates a braking force of the vehicle.

The body system control unit 12020 controls an operation of various devices mounted on a vehicle body in accordance with various programs. For example, the body system control unit 12020 functions as a control device for a keyless entry system, a smart key system, a power window device, or various lamps such as a headlamp, a back lamp, a brake lamp, a turn indicator, or a fog lamp. In this case, the body system control unit 12020 may be inputted with radio waves or signals of various switches transmitted from a portable device that substitutes for a key. The body system control unit 12020 receives an input of these radio waves or signals, and controls a door lock device, a power window device, a lamp, and the like of the vehicle.

The vehicle external information detection unit 12030 detects information about the outside of the vehicle equipped with the vehicle control system 12000. For example, to the vehicle external information detection unit 12030, an imaging unit 12031 is connected. The vehicle external information detection unit 12030 causes the imaging unit 12031 to capture an image of an outside of the vehicle, and receives the captured image. The vehicle external information detection unit 12030 may perform an object detection process or a distance detection process for a person, a vehicle, an obstacle, a sign, a character on a road surface, or the like on the basis of the received image.

The imaging unit 12031 is an optical sensor that receives light and outputs an electric signal according to an amount of received light. The imaging unit 12031 can output the electric signal as an image, or can output as distance measurement information. Furthermore, the light received by the imaging unit 12031 may be visible light or non-visible light such as infrared light.

The vehicle internal information detection unit 12040 detects information inside the vehicle. The vehicle internal information detection unit 12040 is connected with, for example, a driver state detection unit 12041 that detects a state of a driver. The driver state detection unit 12041 may include, for example, a camera that images the driver, and, on the basis of detection information inputted from the driver state detection unit 12041, the vehicle internal information detection unit 12040 may calculate a degree of tiredness or a degree of concentration of the driver, or may determine whether or not the driver is asleep.

On the basis of information inside and outside the vehicle acquired by the vehicle external information detection unit 12030 or the vehicle internal information detection unit 12040, the microcomputer 12051 can operate a control target value of the driving force generation device, the steering mechanism, or the braking device, and output a control command to the drive system control unit 12010. For example, the microcomputer 12051 can perform cooperative control for the purpose of realizing functions of advanced driver assistance system (ADAS) including avoidance of collisions or mitigation of impacts of the vehicle, follow-up traveling on the basis of a distance between vehicles, vehicle speed maintenance traveling, vehicle collision warning, vehicle lane departure warning, and the like.

Furthermore, by controlling the driving force generation device, the steering mechanism, the braking device, or the like on the basis of the information about surroundings of the vehicle acquired by the vehicle external information detection unit 12030 or vehicle internal information detection unit 12040, the microcomputer 12051 may perform cooperative control for the purpose of, for example, automatic driving for autonomously traveling without depending on an operation of the driver.

Furthermore, the microcomputer 12051 can output a control command to the body system control unit 12020 on the basis of information about the outside of the vehicle acquired by the vehicle external information detection unit 12030. For example, the microcomputer 12051 can control a headlamp in accordance with a position of a preceding vehicle or an oncoming vehicle detected by the vehicle external information detection unit 12030, and perform cooperative control for the purpose of antiglare, such as switching a high beam to a low beam.

The sound/image output unit 12052 transmits an output signal of at least one of sound or an image, to an output device capable of visually or audibly notifying, of information, a passenger of the vehicle or outside the vehicle. In the example of FIG. 30, an audio speaker 12061, a display unit 12062, and an instrument panel 12063 are illustrated as the output devices. The display unit 12062 may include, for example, at least one of an on-board display or a head-up display.

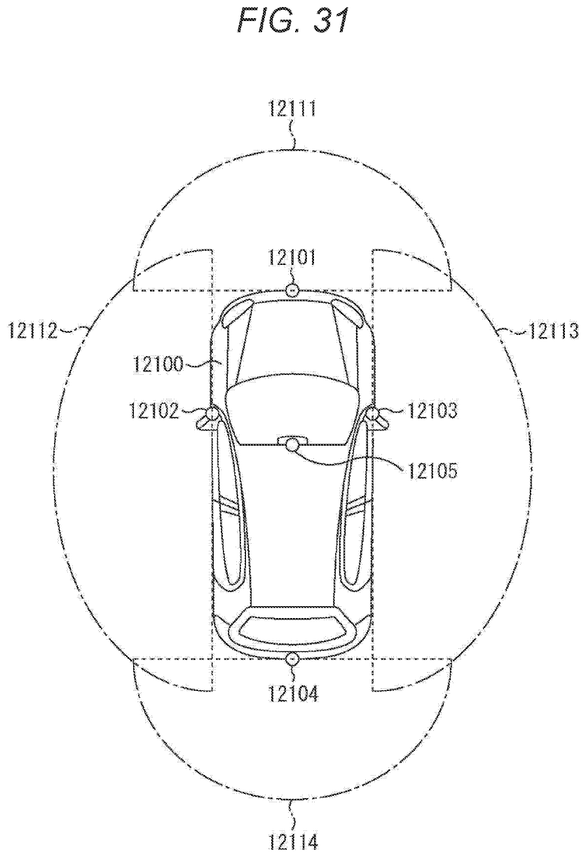

FIG. 31 is a view showing an example of an installation position of the imaging unit 12031.

In FIG. 31, as the imaging unit 12031, a vehicle 12100 includes imaging units 12101, 12102, 12103, 12104, and 12105.

The imaging units 12101, 12102, 12103, 12104, and 12105 are provided at, for example, a front nose, side mirrors, a rear bumper, a back door, an upper part of a windshield in a vehicle cabin, or the like of the vehicle 12100. The imaging unit 12101 provided at the front nose and the imaging unit 12105 provided at the upper part of the windshield in the vehicle cabin mainly acquire an image in front of the vehicle 12100. The imaging units 12102 and 12103 provided at the side mirrors mainly acquire an image of a side of the vehicle 12100. The imaging unit 12104 provided at the rear bumper or the back door mainly acquires an image behind the vehicle 12100. A front image acquired by the imaging units 12101 and 12105 is mainly used to detect preceding vehicles, pedestrians, obstacles, traffic lights, traffic signs, lanes, and the like.

Note that FIG. 31 shows an example of an image capturing range of the imaging units 12101 to 12104. An imaging range 12111 indicates an imaging range of the imaging unit 12101 provided at the front nose, imaging ranges 12112 and 12113 indicate imaging ranges of the imaging units 12102 and 12103 each provided at the side mirrors, and an imaging range 12114 indicates an imaging range of the imaging unit 12104 provided at the rear bumper or the back door. For example, by superimposing image data captured by the imaging units 12101 to 12104, an overhead view image of the vehicle 12100 viewed from above can be obtained.

At least one of the imaging units 12101 to 12104 may have a function of acquiring distance information. For example, at least one of the imaging units 12101 to 12104 may be a stereo camera including a plurality of imaging elements, or an imaging element having pixels for detecting a phase difference.

For example, on the basis of the distance information obtained from the imaging units 12101 to 12104, by obtaining a distance to each solid object within the imaging ranges 12111 to 12114 and a time change of this distance (a relative speed with respect to the vehicle 12100), the microcomputer 12051 can extract, as a preceding vehicle, especially a solid object that is the closest on a travel route of the vehicle 12100, and that is traveling at a predetermined speed (for example, 0 km/h or more) in substantially the same direction as the vehicle 12100. Moreover, the microcomputer 12051 can set an inter-vehicle distance to be secured from a preceding vehicle in advance, and perform automatic brake control (including follow-up stop control), automatic acceleration control (including follow-up start control), and the like. In this way, it is possible to perform cooperative control for the purpose of, for example, automatic driving for autonomously traveling without depending on an operation of the driver.

For example, on the basis of the distance information obtained from the imaging units 12101 to 12104, the microcomputer 12051 can classify solid object data regarding solid objects into a two-wheeled vehicle, an ordinary vehicle, a large vehicle, a pedestrian, a utility pole, and the like, to extract and use for automatic avoidance of obstacles. For example, the microcomputer 12051 distinguishes obstacles around the vehicle 12100 into obstacles that are visible to the driver of the vehicle 12100 and obstacles that are difficult to see. Then, the microcomputer 12051 can determine a collision risk indicating a risk of collision with each obstacle, and provide driving assistance for collision avoidance by outputting an alarm to the driver via the audio speaker 12061 or the display unit 12062, or by performing forced deceleration and avoidance steering via the drive system control unit 12010, when the collision risk is equal to or larger than a set value and there is a possibility of collision.

At least one of the imaging units 12101 to 12104 may be an infrared camera that detects infrared light. For example, the microcomputer 12051 can recognize a pedestrian by determining whether or not a pedestrian exists in a captured image of the imaging units 12101 to 12104. Such recognition of a pedestrian is performed by, for example, a procedure of extracting a feature point in a captured image of the imaging unit 12101 to 12104 as an infrared camera, and a procedure of performing pattern matching processing on a series of feature points indicating a contour of an object and determining whether or not the object is a pedestrian. When the microcomputer 12051 determines that a pedestrian is present in the image captured by the imaging units 12101 to 12104 and recognizes the pedestrian, the sound/image output unit 12052 controls the display unit 12062 so as to superimpose and display a rectangular contour line for emphasis on the recognized pedestrian. Furthermore, the sound/image output unit 12052 may control the display unit 12062 to display an icon or the like indicating a pedestrian at a desired position.

An example of the vehicle control system to which the technology (the present technology) according to the present disclosure can be applied has been described above. The technology according to the present disclosure can be applied to, for example, the imaging unit 12031 and the like among the configurations described above. Specifically, for example, the solid-state imaging device 111 of the present disclosure can be applied to the imaging unit 12031. By applying the technology according to the present disclosure to the imaging unit 12031, performance can be improved.

Note that the present technology is not limited to the above-described embodiments and application examples, and various modifications can be made without departing from the scope of the present technology.

Furthermore, the effects described in this specification are merely examples and are not limited, and other effects may be present.

Furthermore, the present technology can also have the following configurations.

[1]

A solid-state imaging device including: a pixel array unit in which pixels having at least a photoelectric conversion unit configured to perform photoelectric conversion are arranged two-dimensionally;

a rib formed in an outer peripheral portion outside the pixel array unit and extending above the pixel array unit;

a light-shielding material arranged at least in an outer peripheral portion outside the pixel array unit and further arranged below the rib; and

a low-reflection material formed so as to cover at least a part of the light-shielding material.

[2]

The solid-state imaging device according to [1], in which the low-reflection material is formed below the rib.

[3]

The solid-state imaging device according to [1], in which the low-reflection material is formed on a side of the rib.

[4]

The solid-state imaging device according to [1], in which the low-reflection material is formed below the rib and on a side of the rib.

[5]

The solid-state imaging device according to [1], in which

the light-shielding material is arranged in an outer peripheral portion outside the pixel array unit and in at least a part of the pixel array unit, and further arranged below the rib, and

the low-reflection material is formed below the rib and in at least a part of the pixel array unit so as to cover at least a part of the light-shielding material.

[6]

The solid-state imaging device according to [1], in which the light-shielding material is arranged in an outer peripheral portion outside the pixel array unit and in at least a part of the pixel array unit, and further arranged below the rib, and

the low-reflection material is formed on a side of the rib and in at least a part of the pixel array unit so as to cover at least a part of the light-shielding material.

[7]

The solid-state imaging device according to [1], in which

the light-shielding material is arranged in an outer peripheral portion outside the pixel array unit and in at least a part of the pixel array unit, and further arranged below the rib, and

the low-reflection material is formed below the rib, on a side of the rib, and in at least a part of the pixel array unit so as to cover at least a part of the light-shielding material.

[8]

The solid-state imaging device according to [1], in which the low-reflection material is laminated with the light-shielding material via at least one type of oxide film, to be formed below the rib.

[9]

The solid-state imaging device according to [1], in which the low-reflection material is laminated with the light-shielding material via at least one type of oxide film, to be formed on a side of the rib.

[10]

The solid-state imaging device according to [1], in which the low-reflection material is laminated with the light-shielding material via at least one type of oxide film, to be formed below the rib and on a side of the rib.

[11]

The solid-state imaging device according to any one of [1] to [10], in which the low-reflection material is a blue filter.

[12]

The solid-state imaging device according to any one of [1] to [10], in which the low-reflection material is a black filter.

[13]

An electronic device equipped with the solid-state imaging device according to any one of [1] to [12].

### REFERENCE SIGNS LIST

1 Rib
2 First organic material
3 Second organic material
4 Semiconductor substrate
5 First oxide film
6 Light-shielding material
7, 8, 9, 10, 500 Low-reflection material
11 Color filter
12 Second oxide film
100, 100-1, 100-2, 100-3, 100-4, 101 Solid-state imaging device.

1. A solid-state imaging device comprising:
a pixel array unit in which pixels having at least a photoelectric conversion unit configured to perform photoelectric conversion are arranged two-dimensionally;
a rib formed in an outer peripheral portion outside the pixel array unit and extending above the pixel array unit;
a light-shielding material arranged at least in an outer peripheral portion outside the pixel array unit and further arranged below the rib; and
a low-reflection material formed to cover at least a part of the light-shielding material.

2. The solid-state imaging device according to claim 1, wherein the low-reflection material is formed below the rib.

3. The solid-state imaging device according to claim 1, wherein the low-reflection material is formed on a side of the rib.

4. The solid-state imaging device according to claim 1, wherein the low-reflection material is formed below the rib and on a side of the rib.

5. The solid-state imaging device according to claim 1, wherein
the light-shielding material is arranged in an outer peripheral portion outside the pixel array unit and in at least a part of the pixel array unit, and arranged below the rib, and
the low-reflection material is formed below the rib and in at least a part of the pixel array unit to cover at least a part of the light-shielding material.

6. The solid-state imaging device according to claim 1, wherein
the light-shielding material is arranged in an outer peripheral portion outside the pixel array unit and in at least a part of the pixel array unit, and arranged below the rib, and
the low-reflection material is formed on a side of the rib and in at least a part of the pixel array unit to cover at least a part of the light-shielding material.

7. The solid-state imaging device according to claim 1, wherein
the light-shielding material is arranged in an outer peripheral portion outside the pixel array unit and in at least a part of the pixel array unit, and arranged below the rib, and
the low-reflection material is formed below the rib, on a side of the rib, and in at least a part of the pixel array unit to cover at least a part of the light-shielding material.

8. The solid-state imaging device according to claim 1, wherein the low-reflection material is laminated with the light-shielding material via at least one type of oxide film, to be formed below the rib.

9. The solid-state imaging device according to claim 1, wherein the low-reflection material is laminated with the light-shielding material via at least one type of oxide film, to be formed on a side of the rib.

10. The solid-state imaging device according to claim 1, wherein the low-reflection material is laminated with the light-shielding material via at least one type of oxide film, to be formed below the rib and on a side of the rib.

11. The solid-state imaging device according to claim 1, wherein the low-reflection material is a blue filter.

12. The solid-state imaging device according to claim 1, wherein the low-reflection material is a black filter.

13. An electronic device equipped with the solid-state imaging device according to claim 1.
